(19) United States
(12) Patent Application Publication
(10) Pub. No.: US 2026/0080124 A1
(43) Pub. Date: Mar. 19, 2026

(54) SIMULATION APPARATUS AND PROGRAM

(71) Applicant: ROHM CO., LTD., Kyoto (JP)

(72) Inventors: Kenji HAMACHI, Kyoto (JP); Koji TAMANO, Kyoto (JP); Takahiro NISHIYAMA, Kyoto (JP)

(21) Appl. No.: 18/812,177

(22) Filed: Aug. 22, 2024

(30) Foreign Application Priority Data
Aug. 25, 2023 (JP) 2023-137208
Jul. 3, 2024 (JP) 2024-107509

(51) Int. Cl. G06F 30/27; G06F 30/17

(52) U.S. Cl. CPC G06F 30/27; G06F 30/17

(57) ABSTRACT

A simulation apparatus comprises a model storage unit storing a physical model of a physical system configured to generate a physical signal waveform, a sensor model, a machine learning model, and an abnormality determination model; a model arithmetic unit configured to perform arithmetic processing using the physical model, the sensor model, the machine learning model, and the abnormality determination model; and a model setting unit configured to perform setting related to each of the physical model, the sensor model, the machine learning model, and the abnormality determination model, on the basis of an input from an operation input unit.

### CROSS-REFERENCE TO RELATED APPLICATIONS

This nonprovisional application claims priority under 35 U.S.C. § 119(a) on Patent Application No. 2023-137208 filed in Japan on Aug. 25, 2023 and No. 2024-107509 filed in Japan on Jul. 3, 2024, the entire contents of which are hereby incorporated by reference.

### BACKGROUND OF THE INVENTION

### Field of the Invention

The present disclosure relates to a simulation apparatus.

### Description of Related Art

Conventionally, for factory equipment maintenance in the industrial machinery field, it has been expanded to apply artificial intelligence (AI) to condition based maintenance of a mechanical system (see, for example, WO2019/035279).

### BRIEF DESCRIPTION OF THE DRAWINGS

FIG. 1 is a diagram illustrating a structure of a computer according to an exemplary embodiment of the present disclosure.

FIG. 2 is a diagram illustrating a structure of a simulation apparatus according to the exemplary embodiment of the present disclosure.

FIG. 3 illustrates a side view (the left side) and a front view (the right side) of a schematic structural example of a motor.

FIG. 4 is a diagram illustrating a motor model structure.

FIG. 5 is a diagram illustrating an input-output relationship between a motion equation section and a wiring circuit section.

FIG. 6 is a diagram illustrating an example of plot of a counter electromotive constant with respect to a rotation speed.

FIG. 7 is a diagram illustrating an example of plots of motor terminal current, the counter electromotive constant, and motor torque with respect to the rotation speed.

FIG. 8 is a schematic diagram of a plane section illustrating a structural example a DC motor with brushes.

FIG. 9 is a developed view in which the structure illustrated in FIG. 8 is developed in a circumferential direction.

FIG. 10 is a diagram illustrating model parameters in a motor physical model.

FIG. 11 is a diagram illustrating a gap between commutator pieces.

FIG. 12 is a diagram for explaining a contact resistance between the commutator piece and a brush.

FIG. 13 is a diagram illustrating rotational movement of a side of a wiring.

FIG. 14 is a diagram illustrating an example of a magnetic flux density distribution.

FIG. 15 is a diagram illustrating positional deviation between a permanent magnet and the brush.

FIG. 16 is a diagram illustrating length of the side of the wiring.

FIG. 17 is a diagram illustrating distance between the side of the wiring and a rotation axis.

FIG. 18 is a diagram illustrating a filter configuration near motor terminals.

FIG. 19 illustrates a schematic plan view, a schematic perspective view, and a schematic developed view, which show rotational movement of the wiring.

FIG. 20 is a schematic developed view illustrating rotational movement of the wiring.

FIG. 21 is a diagram illustrating an overall picture of the wiring circuit section.

FIG. 22 is a table illustrating a method for calculating the contact resistance.

FIG. 23 is a diagram illustrating a structure of the motor physical model when performing modeling using Simscape (registered trademark)/Simulink (registered trademark).

FIG. 24 is a diagram illustrating a partial structure of a wiring circuit model section.

FIG. 25 is a diagram illustrating an example of a simulation result.

FIG. 26 is a diagram illustrating an example of comparison between simulation and real machine.

FIG. 27 is a diagram illustrating a relationship between the motion equation section and a bearing lubrication deficiency model.

FIG. 28 is a diagram illustrating a relationship between the motion equation section and a bearing damage model.

FIG. 29 illustrates a front view and a cross-sectional side view of a bearing and a shaft.

FIG. 30 is a diagram illustrating parameters of the bearing.

FIG. 31 is a diagram for explaining revolution angle and rotation angle of a rolling element.

FIG. 32 is a diagram illustrating an example of a vibration model of a support system.

FIG. 33 is a diagram illustrating a structural example of a sensor model.

FIG. 34 is a diagram illustrating a structural example of a machine learning model.

FIG. 35 is a diagram illustrating a structure of a three-layer neural network.

FIG. 36 is a diagram illustrating an example of a setting screen for motor type and abnormal state.

FIG. 37 is a diagram illustrating an example of a motor basic setting screen.

FIG. 38 is a diagram illustrating an example of a support system setting screen.

FIG. 39 is a diagram illustrating an example of a first abnormal state setting screen.

FIG. 40 is a diagram illustrating an example of a second abnormal state setting screen.

FIG. 41 is a diagram illustrating an example of a time and deterioration setting screen.

FIG. 42 is a diagram illustrating an example of a sensor setting screen.

FIG. 43 is a diagram illustrating an example of an AI setting screen.

FIG. 44 is a diagram illustrating an example of an abnormality determination setting screen.

FIG. 45 is a diagram illustrating an example of a simulation result screen.

### DETAILED DESCRIPTION OF THE PREFERRED EMBODIMENTS

Hereinafter, an exemplary embodiment of the present disclosure is described with reference to the drawings.

### <Structure of Computer>

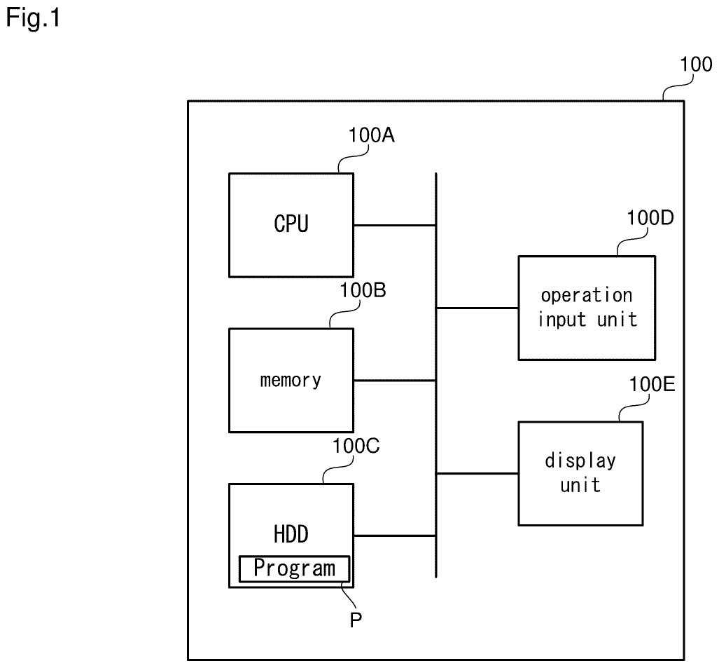

FIG. 1 is a diagram illustrating a structure of a computer 100 according to the exemplary embodiment of the present disclosure. The computer 100 functions as a simulation apparatus according to the present disclosure, which will be described later. The computer 100 is a personal computer (PC), for example. If the computer 100 is a PC, it may be any one of a desktop, laptop and other models.

The computer 100 includes a central processing unit (CPU) 100A, a memory 100B, an auxiliary storage device 100C, an operation input unit 100D, and a display unit 100E.

The CPU 100A includes a control device and an arithmetic device (which are not illustrated). The control device interprets commands in programs and controls individual sections of the computer 100. The arithmetic device is a device that performs arithmetic processing.

The memory 100B is a semiconductor storage device that temporarily stores programs or data. Information stored in the memory 100B is deleted when the computer 100 is powered off.

The auxiliary storage device 100C is constituted of a hard disk drive (HDD), a solid state drive (SSD), or the like, and stores programs or data. The programs stored in the auxiliary storage device 100C are read into the memory 100B. The CPU 100A executes the programs read into the memory 100B.

The operation input unit 100D is a device that is constituted of a keyboard, a mouse, and the like, and provides the computer 100 with operation inputs. Information input from the operation input unit 100D is sent to the memory 100B.

The display unit 100E is constituted of a liquid crystal display, for example, and converts information acquired from the memory 100B into an image so as to output the same.

### <Structure of Simulation Apparatus>

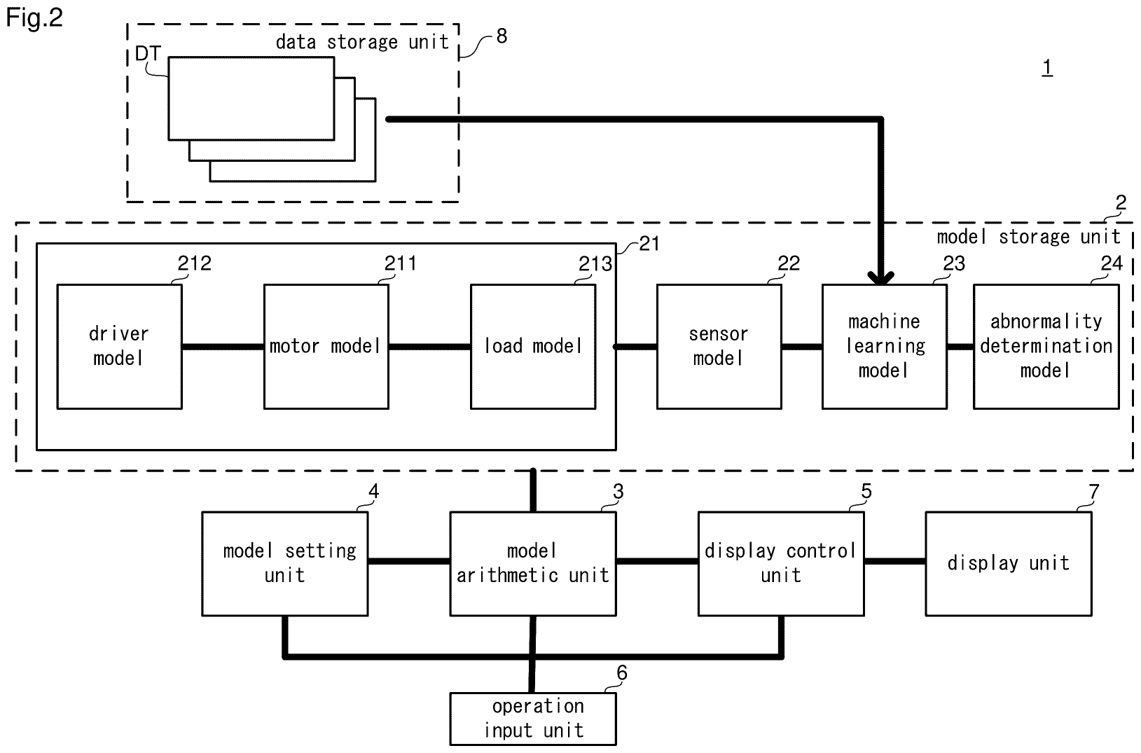

FIG. 2 is a diagram illustrating a structure of a simulation apparatus 1 according to the exemplary embodiment of the present disclosure. The simulation apparatus 1 is an apparatus capable of simulating abnormality detection of a motor system, using machine learning (AI). However, a physical system to which the simulation apparatus of the present disclosure can be applied is not limited to the motor system.

The simulation apparatus 1 includes a model storage unit 2, a model arithmetic unit 3, a model setting unit 4, a display control unit 5, an operation input unit 6, a display unit 7, and a data storage unit 8. A program P stored in the auxiliary storage device 100C of the computer 100 (see FIG. 1) is a program that allows the computer 100 to work as the simulation apparatus 1.

The model storage unit 2 stores a system model 21, a sensor model 22, a machine learning model 23, and an abnormality determination model 24, and is constituted of the auxiliary storage device 100C of the computer 100. The system model 21, the sensor model 22, the machine learning model 23, and the abnormality determination model 24 are constituted as the program P by MATLAB (registered trademark)/Simulink (registered trademark), for example. Note that details of each model will be described later.

Functions of the model arithmetic unit 3, the model setting unit 4, and the display control unit 5 are realized when the CPU 100A executes the program P. Note that the operation input unit 6 and the display unit 7 respectively correspond to the operation input unit 100D and the display unit 100E in the computer 100.

The model arithmetic unit 3 performs arithmetic processing of each model stored in the model storage unit 2, so as to perform simulation. The model setting unit 4 performs setting related to each model stored in the model storage unit 2 (setting of parameters, selection setting of the model, and the like), in accordance with an input from the operation input unit 6. The simulation by the model arithmetic unit 3 is performed in accordance with settings by the model setting unit 4. The display control unit 5 controls the display unit 7 to display a model setting screen described later, in accordance with the input from the operation input unit 6.

In addition, the data storage unit 8 stores state monitor data DT owned by a user who uses the simulation apparatus 1. Note that the data storage unit 8 corresponds to the auxiliary storage device 100C of the computer 100. If the user is considering to introduce abnormality detection by machine learning (AI) to his or her facility, for example, the user allows the data storage unit 8 to store the state monitor data DT obtained by monitoring a motor in the facility. Storing of the state monitor data DT in the data storage unit 8 is performed by obtaining data from the outside of the simulation apparatus 1, via a network or a universal serial bus (USB), for example.

When performing simulation using the state monitor data DT, a predetermined input is performed by the operation input unit 6. Then, the model arithmetic unit 3 allows the machine learning model 23 to input the state monitor data DT, so as to perform learning and inference by the machine learning model 23. After performing learning using normal data included in the state monitor data DT, inference can be performed using abnormal data. As described later, the machine learning model 23 outputs an abnormality degree, and the abnormality determination model 24 performs abnormality determination based on the abnormality degree. In this way, using the state monitor data DT owned by the user, an effect of the abnormality detection by machine learning can be checked, and it is possible to perform simulation suitable for the user's facility environment.

### <System Model>

Next, the system model 21 is described. The system model 21 is a model expressing a physical model of the motor system. Using the system model 21, it is possible to virtually generate a physical signal waveform in a normal or abnormal state of the motor system.

The system model 21 includes a motor model 211, a driver model 212, and a load model 213.

The driver model 212 is a driver model for driving a motor. If the motor is a DC motor with brushes (hereinafter referred to as a BDC motor), for example, the driver described above can be a circuit that applies a DC voltage to the motor using one switch, an H-bridge circuit, or the like. The H-bridge circuit is constituted using two half bridges. The half bridge is constituted of two switching elements connected in series between an application terminal of the DC voltage and a ground terminal (an application terminal of a ground potential). In contrast, if the motor is a brushless DC motor (hereinafter referred to as a BLDC motor), for example, the driver described above can be, for example, a circuit constituted of three half bridges corresponding to a three-phase motor.

The driver in the driver model 212 may be selectable by the model setting unit 4. For instance, if the motor in the motor model 211 is the same BDC motor, the circuit using one switch or the H-bridge circuit as described above may be selectable. In addition, for example, if the motor in the motor model 211 is the BLDC motor, the driver may be selectable in accordance with the number of phases of the motor.

The load model 213 is a model of a target that is driven by the motor in the motor model 211. The drive target is, for example, a fan in a fan device, an arm in an industrial robot, or the like. The load model 213 gives information of external torque to the motor model 211.

### <Motor Model>

Here, the motor model 211 is described. The motor model 211 is a model obtained by physical modeling of the motor (an example of the physical system). The motor described above is, for example, the BDC motor, the BLDC motor, or the like. In this embodiment, the model setting unit 4 can select a type of the motor in the motor model 211. In this case, it may be possible that a plurality of types can be selected for each of the BDC motor or the BLDC motor, for example. The different type of the BDC motor means, for example, the different number of polar pairs, the different number of wirings, the different way of wiring, or the like. The different type of the BLDC motor means, for example, the different number of phases, the different number of poles, the different number of slots, or the like.

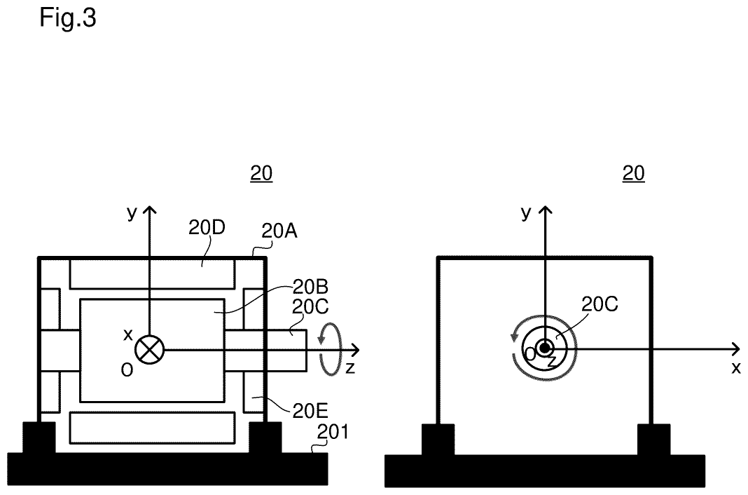

FIG. 3 illustrates a side view (the left side) and a front view (the right side) of a schematic structural example of the motor. Note that FIG. 3 illustrates a common structure without depending on a type of the motor (e.g., the BDC motor, the BLDC motor). Note that the orthogonal coordinate system illustrated in FIG. 3 is a static coordinate system that is fixed to a mount 201. The X-axis, the Y-axis, and the Z-axis are orthogonal to each other. The Z-axis extends in the extending direction of a shaft 20C, and passes the center of the shaft 20C. The Y-axis extends perpendicular to the plane of the mount 201. The X-axis extends in parallel to the plane and extends in the horizontal direction. In FIG. 3, as an example, the origin O of the orthogonal coordinate system is in a rotor 20B.

As illustrated in FIG. 3, a motor 20 is fixed on the mount 201. The motor 20 includes a case 20A, the rotor 20B, the shaft 20C, a stator 20D, and a bearing 20E. The case 20A houses the rotor 20B, the shaft 20C, the stator 20D, and the bearing 20E. The stator 20D is fixed to the case 20A. The rotor 20B is disposed at an inner side of the stator 20D. The shaft 20C protrudes from the rotor 20B to both sides in the rotation axis direction (the Z-axis direction). The shaft 20C is supported in a rotatable manner by the bearing 20E on each side in the rotation axis direction. The bearing 20E is fixed to the case 20A. Note that FIG. 3 illustrates the motor of an inner rotor type in which the rotor 20B is disposed at an inner side of the stator 20D, but the motor may be an outer rotor type in which the rotor is disposed at an outer side of the stator.

For instance, if the motor 20 is the BDC motor, the stator 20D includes a magnet, for example, and the rotor 20B includes a core, wirings, and a commutator. The brush and the commutator included in the BDC motor can contact with each other. When current flows from the brush to the wiring via the commutator, interaction between magnetic force lines generated by the wiring and magnetic force lines generated by the magnet allows the rotor 20B to rotate.

For instance, if the motor 20 is the BLDC motor, the stator 20D include the core and the wiring, for example, while the rotor 20B includes the magnet, and when current flows in the wiring, the rotor 20B rotates.

When the rotor 20B and the shaft 20C rotate about the rotation axis, a load connected to the shaft 20C is driven.

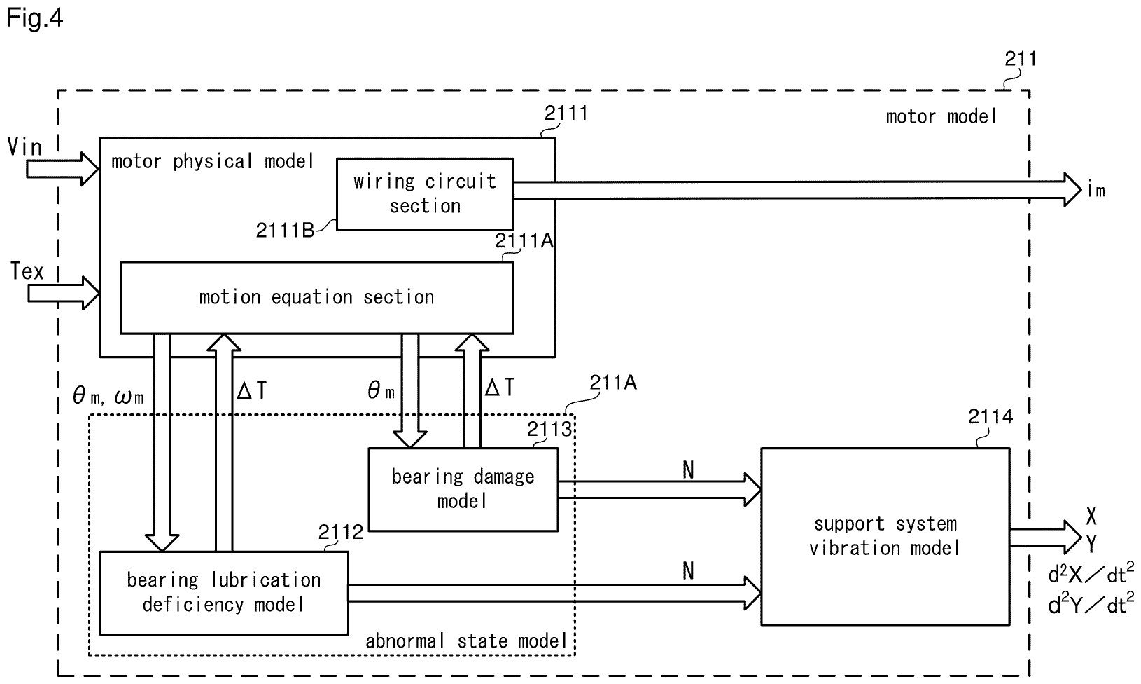

FIG. 4 is a diagram illustrating a structure of the motor model 211. The motor model 211 has a motor physical model 2111. The motor physical model 2111 includes a motion equation section 2111A and a wiring circuit section 2111B.

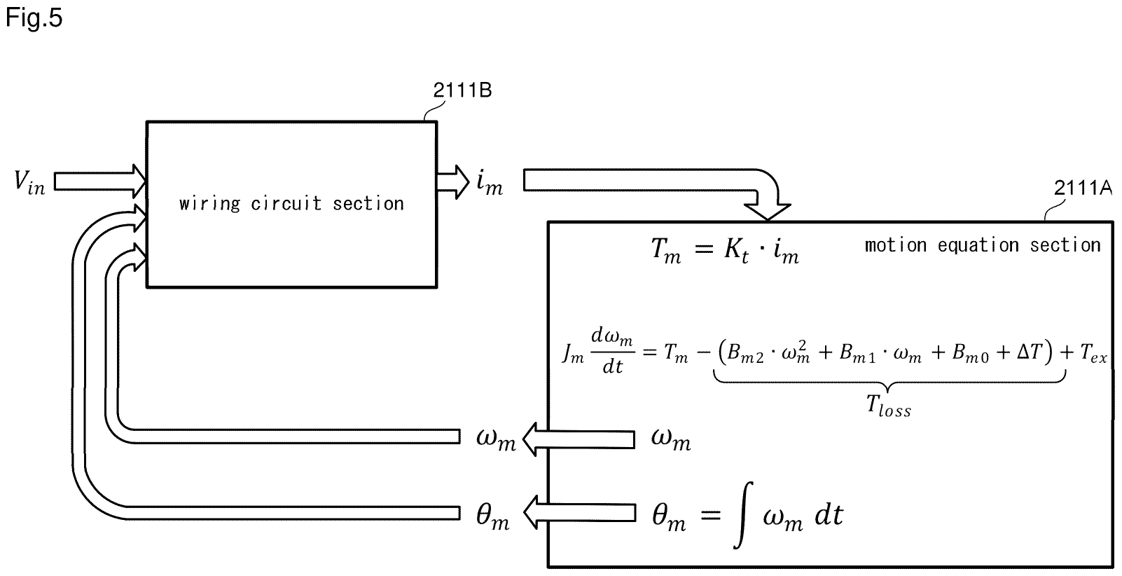

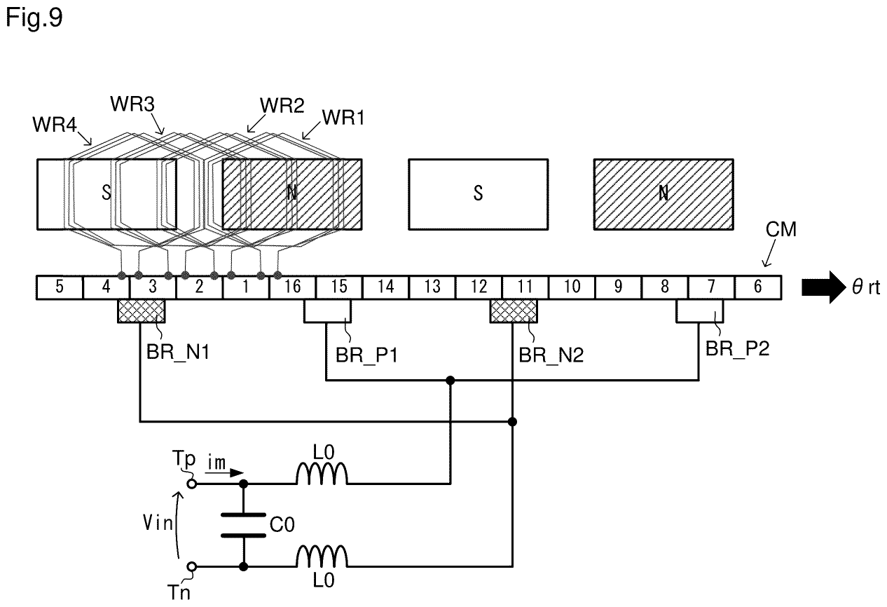

FIG. 5 is a diagram illustrating an input-output relationship between the motion equation section 2111A and the wiring circuit section 2111B. An input voltage Vin is input to the wiring circuit section 2111B, and motor terminal current im is calculated and output. Note that the input voltage Vin is applied between a motor positive electrode terminal Tp and a motor negative electrode terminal Tn as illustrated in FIG. 9 that is referred to later, and the motor terminal current im is current flowing through the motor terminal. The motor terminal current im is input to the motion equation section 2111A, and mechanical angular velocity ωm and the mechanical angle θm of the shaft 20C are calculated and output. The mechanical angular velocity ωm and the mechanical angle θm are fed back to the wiring circuit section 2111B.

The motion equation section 2111A has the following equation (1) as an equation of motion:

$${I}_{M} \frac{d {ω}_{m}}{dt} = {T}_{m} - ( {B}_{m 2} \cdot {ω}_{m}^{2} + {B}_{m 1} \cdot {ω}_{m}^{} + {B}_{m 0} + Δ T ) + {T}_{ex} \qquad ( 1 )$$

where Jm is an inertia of a rotating part of the motor 20 (the rotor 20B and the shaft 20C), Tm is a motor torque, and Tex is an external torque.

The motor torque Tm is expressed by the following equation (2):

$${T}_{m} = {K}_{t} \cdot {i}_{m} \qquad ( 2 )$$

where Kt is a torque constant.

The motor generates a torque by interaction between a magnetic flux distribution due to the permanent magnet and a magnetic flux distribution due to the wiring current. Contribution of the magnetic flux distribution due to the permanent magnet on the torque is determined by a shape and layout of magnetic poles, and further by a geometric positional relationship of the wirings, and it is a constant gain-like contribution without a relation to the rotation speed or the motor terminal current value. Therefore, as expressed by the above equation (2), the motor torque Tm is the product of the torque constant Kt as a constant coefficient and the motor terminal current im.

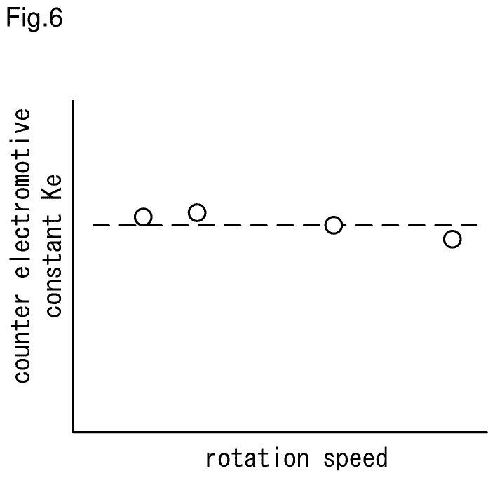

In addition, the torque constant Kt and a counter electromotive constant Ke have a relationship of Kt=Ke, while a counter electromotive voltage Vbemf and the mechanical angular velocity ωm have a relationship of Vbemf=Ke×ωm. The counter electromotive voltage is a voltage generated across the motor terminals of the motor as a modeling target, in the state where a shaft of the motor as the modeling target is connected to another motor, and the shaft is rotated at constant speed by the another motor. While changing the rotation speed, the counter electromotive voltage Vbemf was measured, and Ke=Vbemf/om was calculated. As a result, the counter electromotive constant was substantially constant regardless of the rotation speed, as illustrated in FIG. 6. Therefore, the counter electromotive constant can be regarded as a constant, and the average value of the plotted counter electromotive constants was set to the counter electromotive constant Ke. This value can be set as a value of the torque constant Kt. In this way, the counter electromotive constant Ke is a constant, which is a basis of the above equation (2).

Here, in the above equation (1) as the equation of motion, the left side expresses the product of the inertia Jm and a mechanical angular acceleration, while the right side expresses a composite torque of the motor torque Tm generated when the input voltage Vin is applied to the motor terminal, a loss torque Tloss as a combination of various losses, and the external torque Tex. The external torque Tex corresponds to a torque output from the load model 213, a torque output from a human or environment, and the like.

A component of the loss torque Tloss expressed by

$${B}_{m 2} \cdot {ω}_{m}^{2} + {B}_{m 1} \cdot {ω}_{m} + {B}_{m 0}$$

is a loss torque in a normal state. Note that Bm0, Bm1, and Bm2 are loss coefficients.

As described above, the loss torque is assumed to be expressed by a quadratic expression of the mechanical angular velocity ωm. The assumption of the loss torque is determined by utilizing that the motor torque Tm minus loss torque equals zero, i.e., the following equation holds in the normal state at constant rotation speed, and in the state where no external torque is applied.

$${T}_{m} - ( {B}_{m 2} \cdot {ω}_{m}^{2} + {B}_{m 1} \cdot {ω}_{m} + {B}_{m 0} ) = 0$$

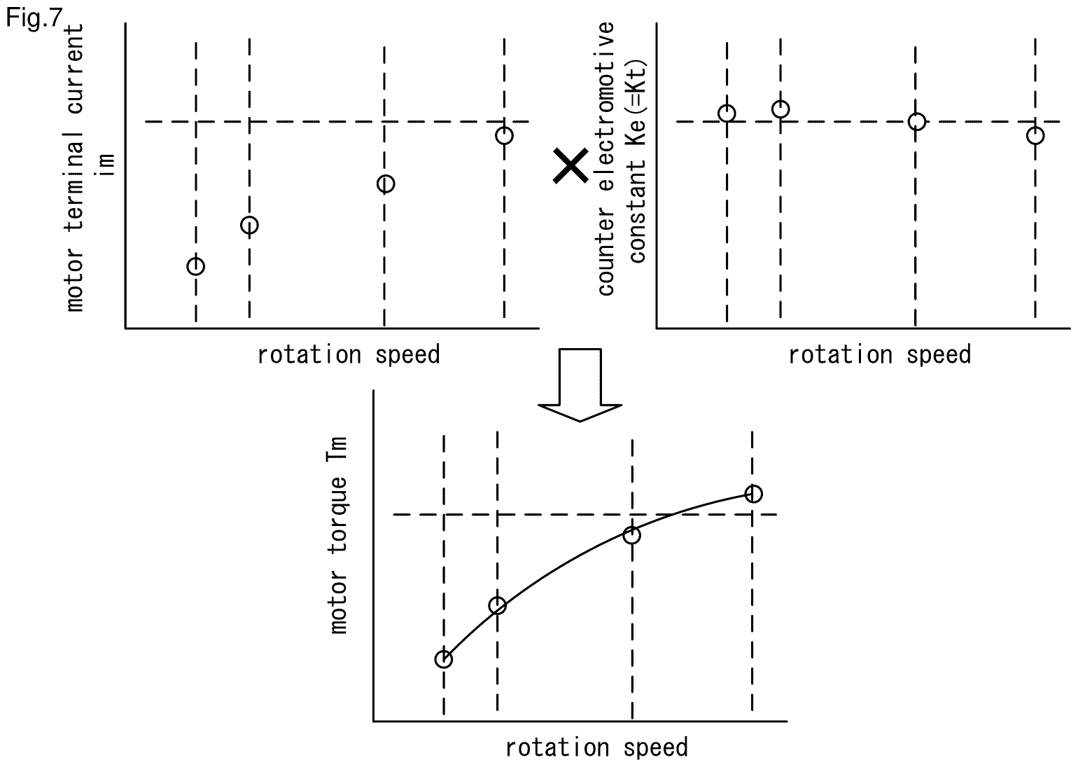

First, while changing the rotation speed, and while changing the input voltage Vin at each rotation speed, the average value of the motor terminal current is measured. A result of the measurement is illustrated in FIG. 7, at the upper left side. Using the average value of the motor terminal current and the counter electromotive constant Ke (=torque constant Kt) described above and illustrated in FIG. 6, the motor torque Tm was calculated from the above equation (2). As illustrated in FIG. 7, the motor torque Tm is obtained for each rotation speed. Because the motor torque Tm and the loss torque match each other when rotating at constant speed, the plots of the motor torque Tm illustrated in FIG. 7 can be regarded as plots of the loss torque. If the plots illustrated in FIG. 7 is regressed with a quadratic equation, a determined coefficient is good, and hence the loss torque is expressed by a quadratic equation of the mechanical angular velocity ωm as described above.

### <BDC Motor>

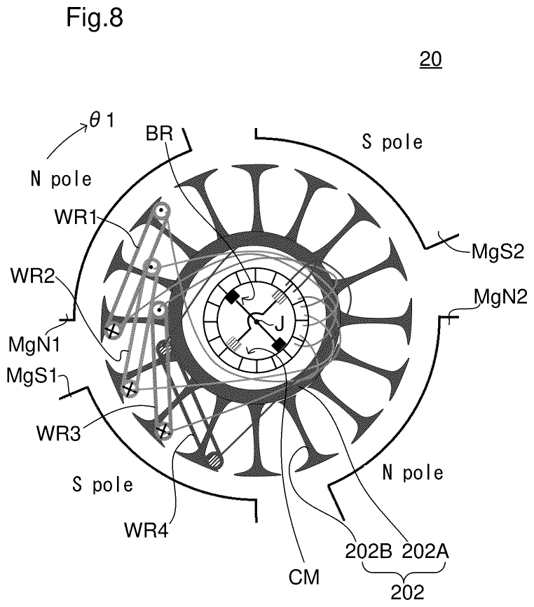

Here, before describing the wiring circuit section 2111B, the BDC motor as an example of the modeling target of the wiring circuit section 2111B is described in more detail. FIG. 8 is a plane section schematic diagram illustrating a structural example of the motor 20, which is the BDC motor. FIG. 8 is a diagram viewed in a direction of a rotation axis J. The rotation axis J is identical to the Z-axis described above. Note that in the following description, the direction in which the rotation axis J extends is referred to as an axial direction, the direction around the rotation axis J is referred to as a circumferential direction, and the direction perpendicular to the rotation axis J is referred to as a radial direction.

The stator 20D includes a permanent magnet Mg and a brush BR. In the structure of FIG. 8, the permanent magnet Mg includes magnets MgS1, MgN1, MgS2, and MgN2. The magnets MgS1, MgN1, MgS2, and MgN2 respectively put S pole, N pole, S pole, and N pole in the circumferential direction on the inner side in the radial direction. In other words, the magnetic poles of S pole and N pole are alternately disposed in the circumferential direction on the inner side in the radial direction.

The brush BR includes positive electrode brushes and negative electrode brushes as described later. The brushes of different polarities are alternately disposed in the circumferential direction.

The rotor 20B includes a core 202, wirings WR and commutator pieces CM. The core 202 is constituted of, for example, electromagnetic steel sheets laminated in the axial direction. The core 202 is disposed on the inner side in the radial direction of the permanent magnet Mg. The core 202 includes an annular part 202A and teeth 202B. The annular part 202A extends in the axial direction and is formed in an annular shape in the circumferential direction. The teeth 202B protrude from an outer periphery surface of the annular part 202A outward in the radial direction. A plurality of the teeth 202B are arranged in the circumferential direction.

In the structure of FIG. 8, the wiring WR includes 16 wirings, i.e., wirings WR1 to WR16. Note that FIG. 8 illustrates only typical wirings WR1 to WR4. Each of the wirings WR is wound on one of the teeth 202B so as to pass one side in the circumferential direction (illustrated as 01) of the teeth 202B and the other side in the circumferential direction of another teeth 202B positioned next to the next teeth 202B in the other side in the circumferential direction. The teeth 202B wound by the wirings WR are shifted one by one in the circumferential direction. In this way, FIG. 8 illustrates the structure of concentrated winding.

The commutator pieces CM are disposed on the inner side in the radial direction of the core 202 and on the outer side in the radial direction of the brush BR. In the structure of FIG. 8, the commutator pieces CM include 16 commutator pieces, i.e., commutator pieces CM1 to CM16 (with no numerals in FIG. 8). The commutator pieces CM1 to CM16 are arranged in an annular shape in the circumferential direction. One and the other lead wires of each of the wirings WR are respectively connected to the commutator pieces CM neighboring in the circumferential direction. The commutator pieces CM connected to each of the wirings WR are shifted one by one in the circumferential direction.

The commutator pieces CM can contact the brush BR. When the rotor 20B rotates, the commutator pieces CM revolves, and the commutator piece CM that contact the brush BR, as well as its contact resistance, changes as time lapses.

FIG. 9 is a developed view in which the structure illustrated in FIG. 8 is developed in the circumferential direction. FIG. 9 illustrates a rotation direction Ort of the rotor 20B. The rotation direction Ort is the same direction as one side θ1 in the circumferential direction illustrated in FIG. 8. The S poles and N poles are arranged along the rotation direction Ort. In addition, the commutator pieces CM1 to CM16 are arranged along the rotation direction Ort. Specifically, the commutator pieces CM16, CM15, and so on are arranged in order along the rotation direction Ort. When reaching the commutator piece CM1, the commutator piece returns to CM16. In other words, the commutator pieces CM are arranged in a loop along the rotation direction Ort.

As described above, one and the other lead wires of the wiring WR are respectively connected to the commutator pieces CM neighboring in the circumferential direction. Specifically, as illustrated in FIG. 9, one of the lead wires of the wiring WR1 is connected to the commutator pieces CM16, and the other is connected to the commutator pieces CM1. One of the lead wires of the wiring WR2 is connected to the commutator pieces CM1, and the other is connected to the commutator pieces CM2. One of the lead wires of the wiring WR3 is connected to the commutator pieces CM2, and the other is connected to the commutator pieces CM3. One of the lead wires of the wiring WR4 is connected to the commutator pieces CM3, and the other is connected to the commutator pieces CM4. In the same manner, the lead wires of the wirings WR5 to WR16 are connected to the commutator pieces CM. Note that FIG. 9 illustrates only typical wirings WR1 to WR4. In this way, the wirings WR are connected in series via the commutator pieces CM, so as to form a loop circuit.

In addition, the brush BR includes positive electrode brushes BR_P1 and BR_P2, and negative electrode brushes BR_N1 and BR_N2. The negative electrode brush BR_N1, the positive electrode brush BR_P1, the negative electrode brush BR_N2, and the positive electrode brush BR_P2 are arranged in order along the rotation direction θrt.

When the rotor 20B rotates, the commutator pieces CM1 to CM16 move in the rotation direction θrt, so as to sequentially change the commutator pieces CM that contact the positive electrode brushes BR_P1 and BR_P2, and the negative electrode brushes BR_N1 and BR_N2. As an example, FIG. 9 illustrates the state where the negative electrode brush BR_N1 contacts the commutator pieces CM4 and CM3, the positive electrode brush BR_P1 contacts the commutator pieces CM16 and CM15, the negative electrode brush BR_N2 contacts the commutator pieces CM12 and CM11, and the positive electrode brush BR_P2 contacts the commutator pieces CM8 and CM7. The wiring WR moves together with the commutator pieces CM along the rotation direction θrt, so as to cross magnetic flux of the magnetic poles.

### <Wiring Circuit Unit>

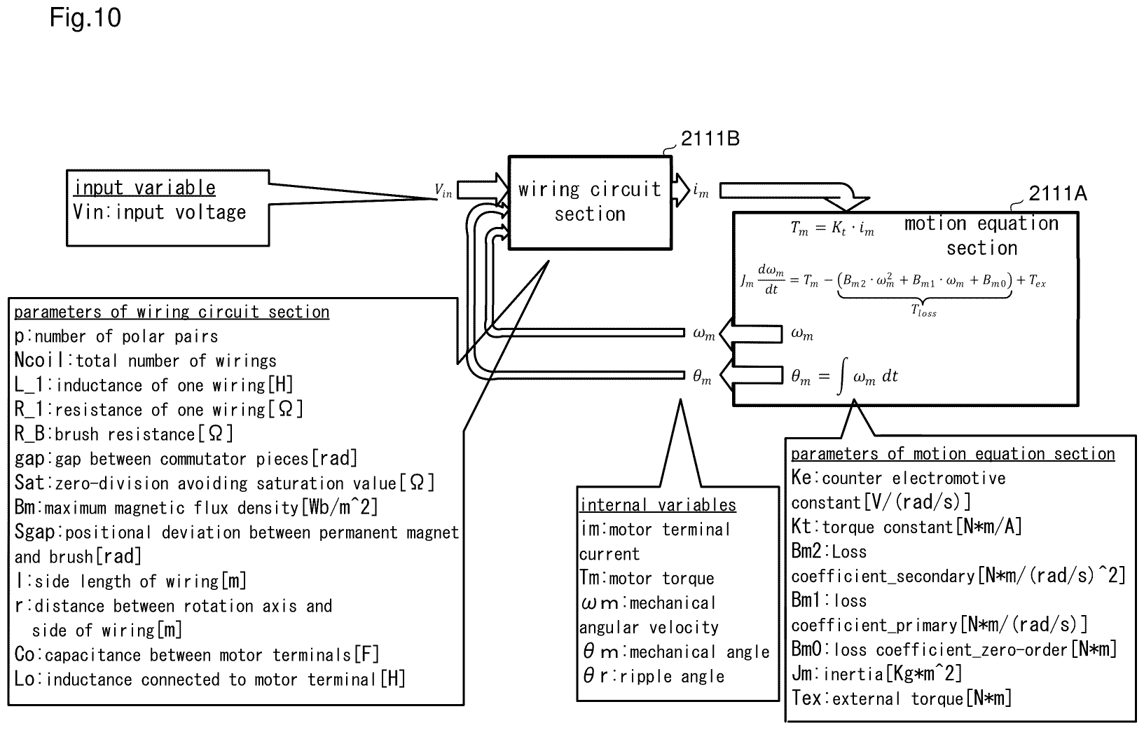

The wiring circuit section 2111B is a model in which geometric arrangement of the wirings WR, the permanent magnets Mg, the brushes BR, and the commutator pieces CM in the motor 20 (the BDC motor) is simply modeled. FIG. 10 illustrates model parameters in the motor physical model 2111. Hereinafter, using parameters in the wiring circuit section 2111B illustrated in FIG. 10, details of the wiring circuit section 2111B are described. Note that FIG. 10 also illustrates parameters in the motion equation section 2111A described above, as well as input variables and internal variables in the motor physical model 2111. The external torque Tex is regarded as a parameter, but it may be regarded as an input variable.

The number of polar pairs p is the number of pairs of magnetic poles of the permanent magnets Mg. The structure of FIG. 9 (FIG. 8) has two pairs of the N poles and the S poles, and hence the number of polar pairs p is two. The total number of wirings Ncoil is the total number of the wirings WR. In the structure of FIG. 9, the total number of wirings Ncoil is 16.

In the structure of FIG. 9, for example, inductance L_1 of one wiring WR and resistance R_1 of one wiring WR1 are measured as a two parallel circuits of eight wirings in series at a midpoint of the loop circuit of the wirings WR in 180 degrees symmetry, and values of them of one wiring WR can be calculated and set as the average values.

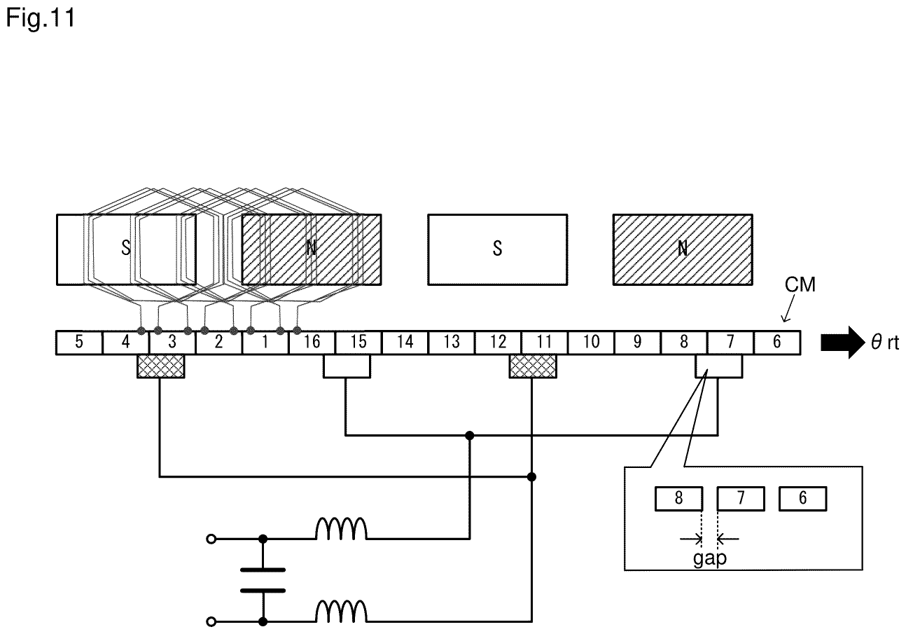

In reality, there is a gap between neighboring commutator pieces CM. As illustrated in FIG. 11, when the gap between the commutator pieces CM is exaggerated and illustrated, the gap between the commutator pieces “gap” is set as a distance. The gap between the commutator pieces “gap” is set by a unit (rad) of ripple angle θr described later. The gap between the commutator pieces “gap” is set on the basis of observation results of a real machine.

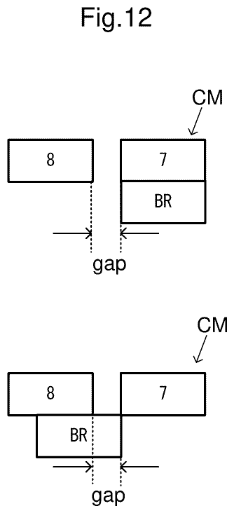

Brush resistance R_B is a contact resistance when the brush BR contacts the commutator piece CM in such a manner that a width of the brush BR just coincides a width of the commutator piece CM, as illustrated in the upper part of FIG. 12. FIG. 12 illustrates an example of a case where the brush BR contacts the commutator piece CM7. In this case, the contact resistance between the commutator piece CM and the brush BR becomes minimum. The brush resistance R_B is adjusted so that a waveform of the motor terminal current im (a ripple waveform) matches between the real machine and the model.

If the contact width between the brush BR and the commutator piece CM is very small, an extreme contact resistance becomes infinite. In the lower part of FIG. 12, there is illustrated an example of the state where the contact width between the brush BR and the commutator piece CM7 is very small. However, it is difficult to perform calculation including infinity in simulation, and such an extreme state is considered not to have occurred in reality. Therefore, as an upper limit value of the contact resistance, a saturation value Sat is set to avoid dividing by zero. The saturation value Sat is adjusted so that the waveform of the motor terminal current im (the ripple waveform) matches between the real machine and the model.

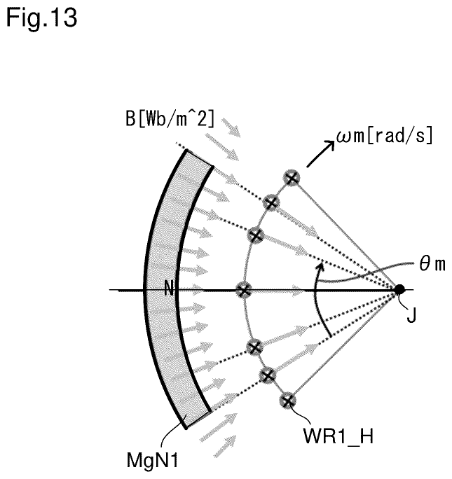

FIG. 13 is a cross-sectional plan view schematically illustrating movement of a side WR1_H of the wiring WR1 about the rotation axis J, and a magnetic flux density B of the permanent magnet MgN1 (the N pole on the inner side in the radial direction), when the side WR1_H is focused. The side WR1_H is a side of the wiring WR1 that extends in the axial direction at an end part on the opposite side in the rotation direction θrt. As illustrated in FIG. 13, the state where the side WR1_H is positioned on a line segment connecting the rotation axis J and the end part on the opposite side in the rotation direction θrt of the permanent magnet MgN1 is defined as that the mechanical angle θm equals zero, and the magnetic flux density B of the magnetic flux passing the side WR1_H is determined depending on the mechanical angle θm.

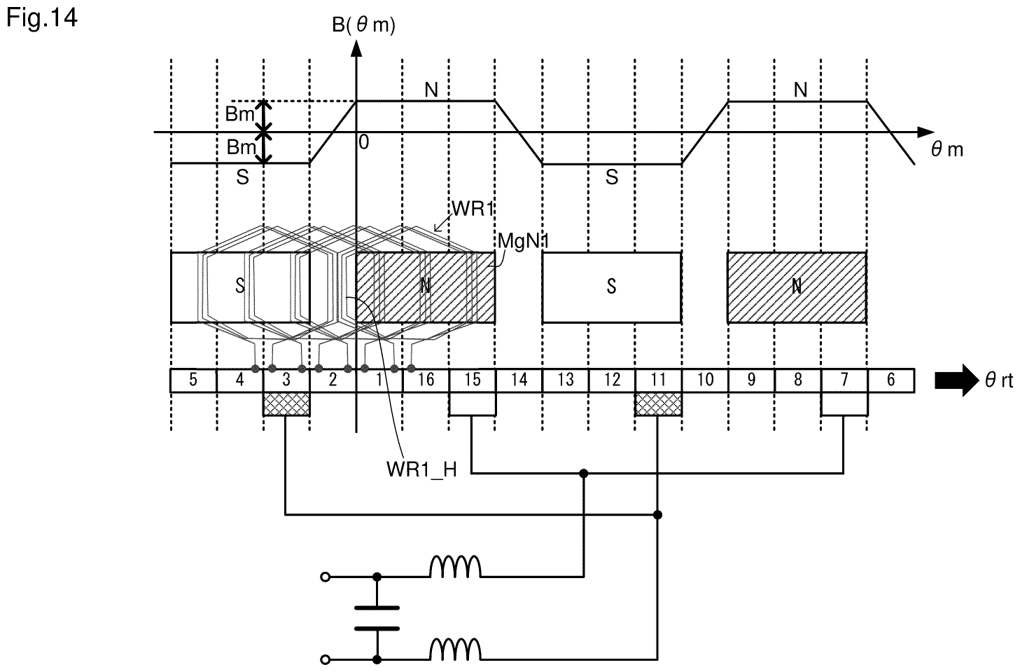

Thus, as illustrated in FIG. 14, the magnetic flux density B is defined as a function B(θm) of the mechanical angle θm, and a magnetic flux density distribution is set. In this case, a maximum magnetic flux density Bm is set as a parameter, and B equals +Bm in the range where the N pole is arranged on the inner side in the radial direction, while B equals-Bm in the range where the S pole is arranged on the inner side in the radial direction. Note that the polarity of the magnetic flux density B is positive in the direction toward the rotation axis J as illustrated in FIG. 13. In the range between the N pole and the S pole, the magnetic flux density B is set to change between +Bm and −Bm. Although the magnetic flux density B is set to change linearly between +Bm and −Bm in FIG. 14, the manner of change is not limited to this. The magnetic flux density distribution can be set by the maximum magnetic flux density Bm and an equation block. Note that the wirings WR2 to WR16 have relative positions to the wiring WR1, and hence the magnetic flux density distribution of the side of each wiring corresponding to the side WR1_H is determined depending on the mechanical angle θm.

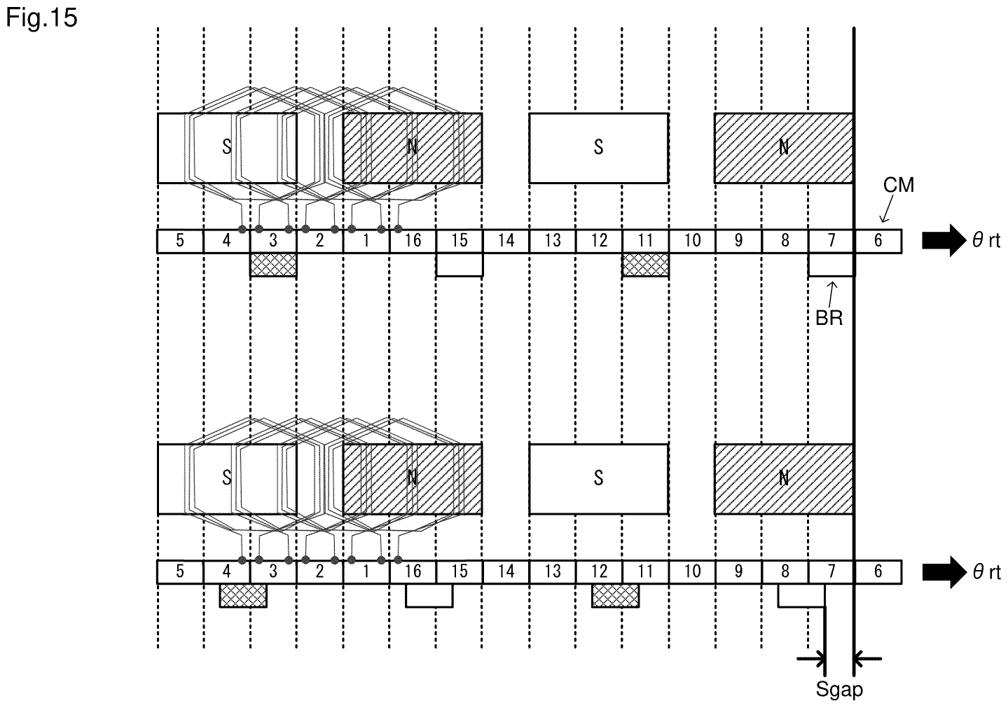

A positional deviation Sgap (rad) is a parameter indicating a positional relationship between the magnetic pole of the permanent magnet Mg and the brush BR. In the example illustrated in FIG. 15, the upper part illustrates a reference state of the positional relationship between the magnetic pole of the permanent magnet Mg and the brush BR (similar to FIG. 14), while the lower part illustrates the case where the brush BR is shifted, in which the positional deviation Sgap is defined. As handling of the positional deviation Sgap in the model, a reference position (origin) of the magnetic flux density distribution can be changed in accordance with the positional deviation Sgap. It is because the magnetic flux density changes with respect to the wiring WR if there is the positional deviation Sgap, even if the mechanical angle θm is the same, i.e., even if the position of the commutator piece CM is the same with respect to the brush BR. The positional deviation Sgap is set on the basis of observation results of a real machine.

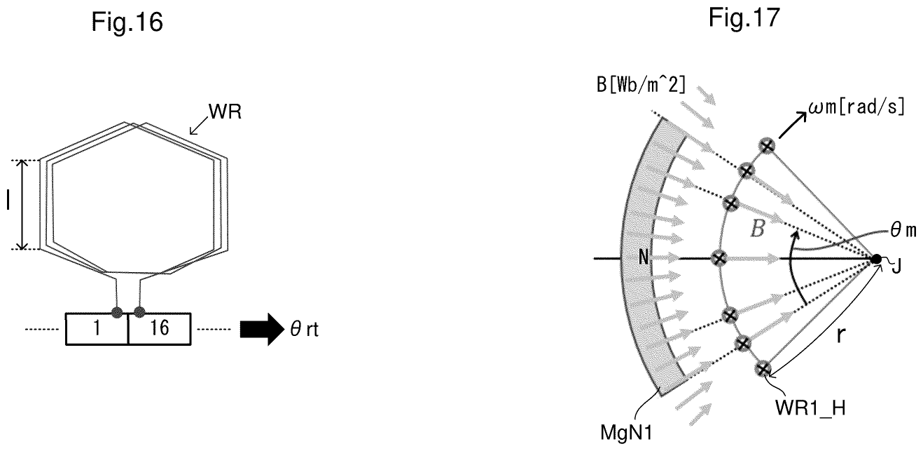

As illustrated in FIG. 16, a side length 1 of the wiring is a parameter indicating a length of the side of the wiring WR extending in the axial direction at the end part in the rotation direction θrt. Note that in the case of the wiring WR1, the side length 1 of the wiring corresponds to the length of the side WR1_H described above. The length 1 is set on the basis of observation results of a real machine.

A distance r between the rotation axis and the side of the wiring is a parameter indicating a distance in the radial direction between the rotation axis J and the side WR_H. FIG. 17 (similar to FIG. 13) illustrates an example of the distance r for the side WR1_H of the wiring WR1. The distance r is set on the basis of observation results of a real machine.

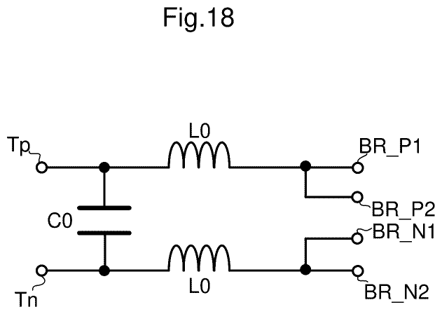

FIG. 18 is a diagram illustrating a circuit structure of the motor terminals and their vicinity (which is also illustrated in FIG. 9 and the like). A capacitor CO is connected between the motor positive electrode terminal Tp and the motor negative electrode terminal Tn. Inductors L0 are connected to the motor positive electrode terminal Tp and the motor negative electrode terminal Tn, respectively. One end of one of the inductors L0 is connected to the motor positive electrode terminal Tp, and the other end thereof is connected to the positive electrode brushes BR_P1 and BR_P2. One end of the other inductor L0 is connected to the motor negative electrode terminal Tn, and the other end thereof is connected to the negative electrode brushes BR_N1 and BR_N2. The capacitor CO and the inductors L0 constitute an LC filter. The LC filter is used for reducing pulse-like noise that is generated when the commutator piece CM and the brush BR are switched. The capacitance of the capacitor CO and the inductance of the inductor L0 are set as parameters, respectively.

Next, an induced electromotive voltage generated in the wiring WR is described. Each of the wirings WR1 to WR16 crosses the magnetic flux of the permanent magnet Mg, and hence the induced electromotive voltage is generated in each of the wirings WR1 to WR16. As described above, the magnetic flux density distribution B is set as a function of the mechanical angle θm. Using this set magnetic flux density distribution, the induced electromotive voltage is calculated for each of the wirings WR1 to WR16 on the basis of temporal change of the magnetic flux that interlinks the same.

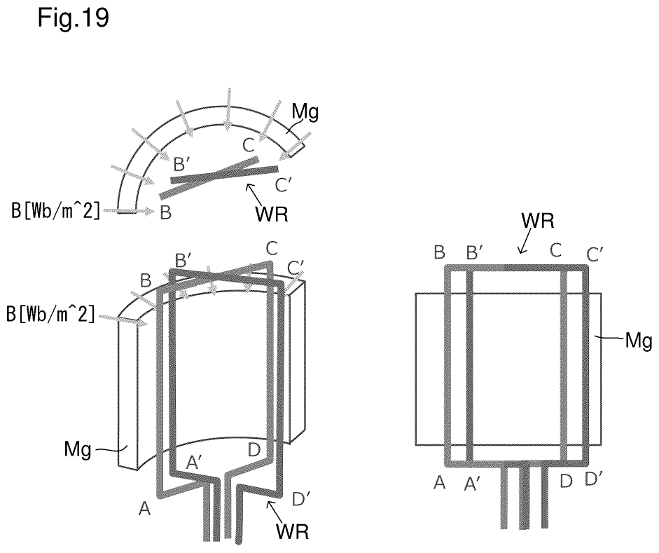

FIG. 19 illustrates a schematic plan view, a schematic perspective view, and a schematic developed view, which show the state where one wiring WR is moved when the rotor 20B rotates. It is supposed that the wiring WR is moved from the state shown by ABCD to the state expressed by A′ B′ C′ D′.

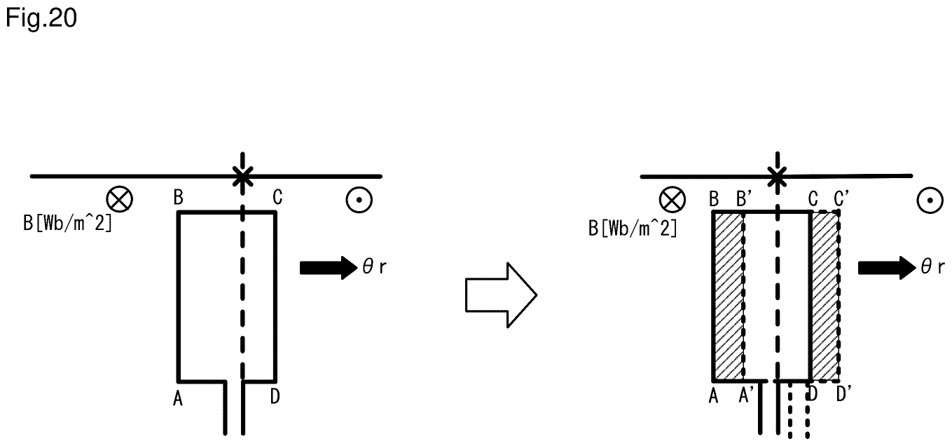

Here, with reference to a developed view illustrated in FIG. 20, an area DCC′D′ scanned by a forward side CD in the rotation direction θrt is an area that is increased by rotational movement of the wiring WR, and is expressed as a plus area. In contrast, an area ABB′A′ scanned by a backward side BA in the rotation direction θrt is an area that is decreased by rotational movement of the wiring WR, and is expressed as a minus area. In addition, the area A′B′CD is an area that does not change before and after the rotational movement, and the magnetic flux that penetrates this area also does not change, so as not to contribute to a magnetic flux change Δφ. As a result of the above discussion, the magnetic flux change Δφ is obtained as the product of the area with the symbols and the magnetic flux density penetrating the area. Therefore, the induced electromotive voltage e_{coil, No.} is expressed as follows.

$${e}_{coil , No .} = Δφ / Δ t = ( ( magnetic flux density at position of forward side ) \times ( area scanned by forward side ) + ( magnetic flux density at position of backward side ) \times ( - ( area scanned by backward side ) ) ) / Δ t$$

Note that e_{coil, No.} is the induced electromotive voltage generated in the wiring expressed by No., i.e., a wiring number (e.g., WR1 if No.=1).

In addition, using the side length l of the wiring and the distance r between the rotation axis and the side of the wiring, the plus area and the minus area described above are calculated as follows: plus area=1×rωm, and minus area=−1×rωm.

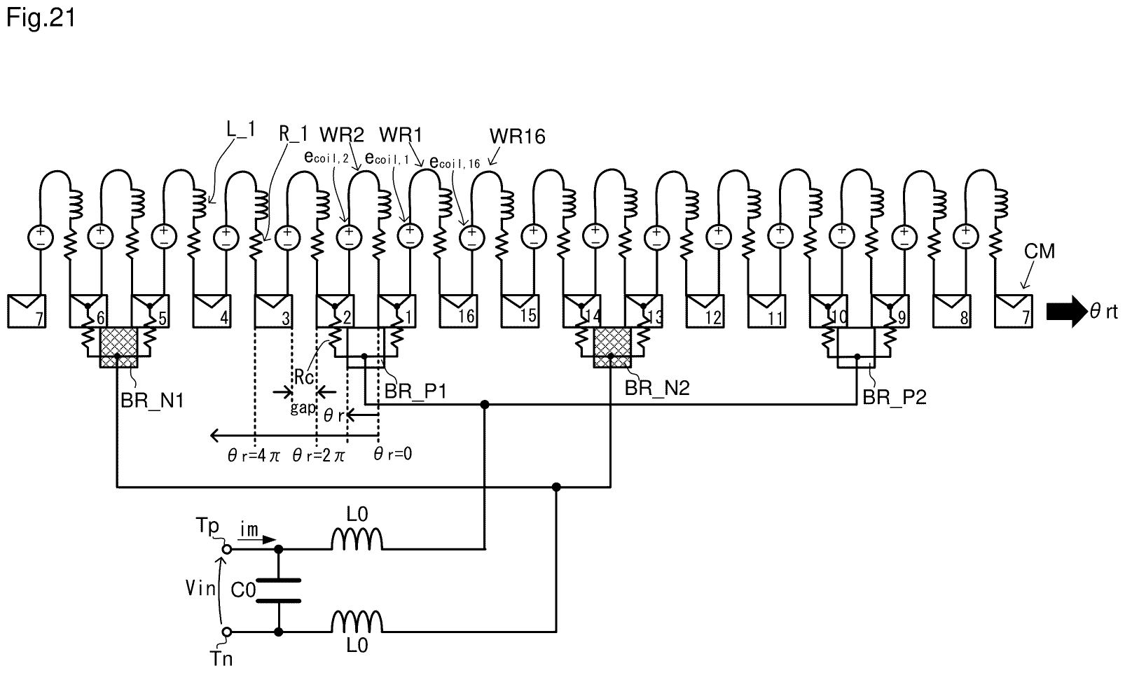

FIG. 21 is a diagram illustrating an overall picture of the wiring circuit section 2111B. The induced electromotive voltage e_{coil, No.} was modeled as output from a voltage source inserted in series to the inductance L_1 and the resistance R_1, in each of the wirings WR1 to WR16.

In addition, the ripple angle θr illustrated in FIG. 21 is described. The focused brush BR is referred to as a predetermined brush (the positive electrode brush BR_P1 in FIG. 21), and the focused commutator piece CM is referred to as a predetermined commutator piece (the commutator piece CM2 in FIG. 21). Then, a contact resistance Rc between the predetermined brush and the predetermined commutator piece is determined as follows.

The commutator piece CM that is adjacent to the predetermined commutator piece on the side in the rotation direction θrt is referred to as a forward commutator piece (the commutator piece CM1 in FIG. 21), and the commutator piece CM that is adjacent to the predetermined commutator piece on the opposite side in the rotation direction θrt is referred to as a backward commutator piece (the commutator piece CM3 in FIG. 21). Then, the state where a backward end part of the predetermined brush coincides a backward end part of the forward commutator piece (the state where the width of the predetermined brush just coincides the width of the forward commutator piece) is defined by “ripple angle θr=0”, and a distance between the backward end part of the predetermined brush and the backward end part of the forward commutator piece is expressed as the ripple angle θr (rad). In the state where the backward end part of the predetermined brush coincides a backward end part of the predetermined commutator piece (the state where the width of the predetermined brush just coincides the width of the predetermined commutator piece), ripple angle θr equals 2π. In the state where the backward end part of the predetermined brush coincides the backward end part of the backward commutator piece (the state where the width of the predetermined brush just coincides the width of the backward commutator piece), ripple angle θr equals 4π. The ripple angle θr can be converted from the mechanical angle θm.

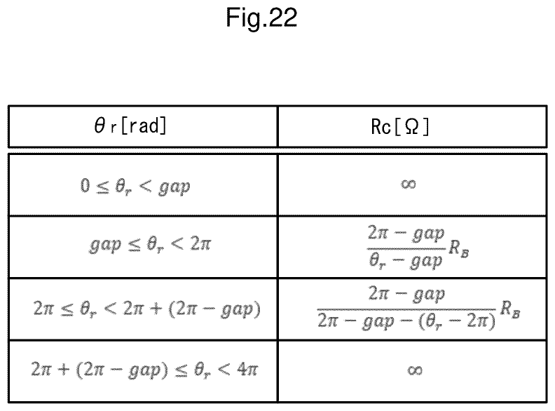

On the basis of the ripple angle θr, the contact resistance Rc between the predetermined brush and the predetermined commutator piece can be calculated as shown in the table illustrated in FIG. 22. Note that RB in FIG. 22 corresponds to the brush resistance R_B. In addition, outside the range of the ripple angle θr illustrated in FIG. 22, the contact resistance becomes infinite. As described above, however, if the calculated contact resistance Rc exceeds the saturation value Sat, contact resistance Rc equals Sat.

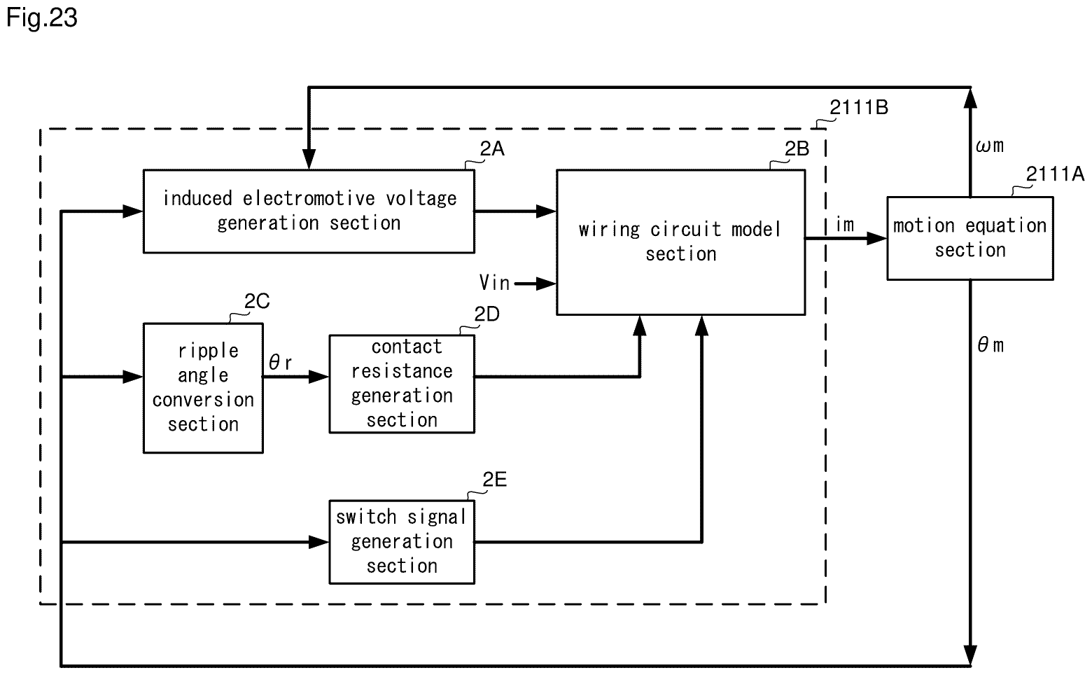

FIG. 23 is a diagram illustrating a structure of the motor physical model 211 when modeling is performed by Simscape (registered trademark)/Simulink (registered trademark).

The motion equation section 2111A receives the motor terminal current im output from the wiring circuit section 2111B, and outputs the mechanical angle θm and the mechanical angular velocity ωm, so as to feedback the same to the wiring circuit section 2111B.

The wiring circuit section 2111B includes an induced electromotive voltage generation section 2A, a wiring circuit model section 2B, a ripple angle conversion section 2C, a contact resistance generation section 2D, and a switch signal generation section 2E.

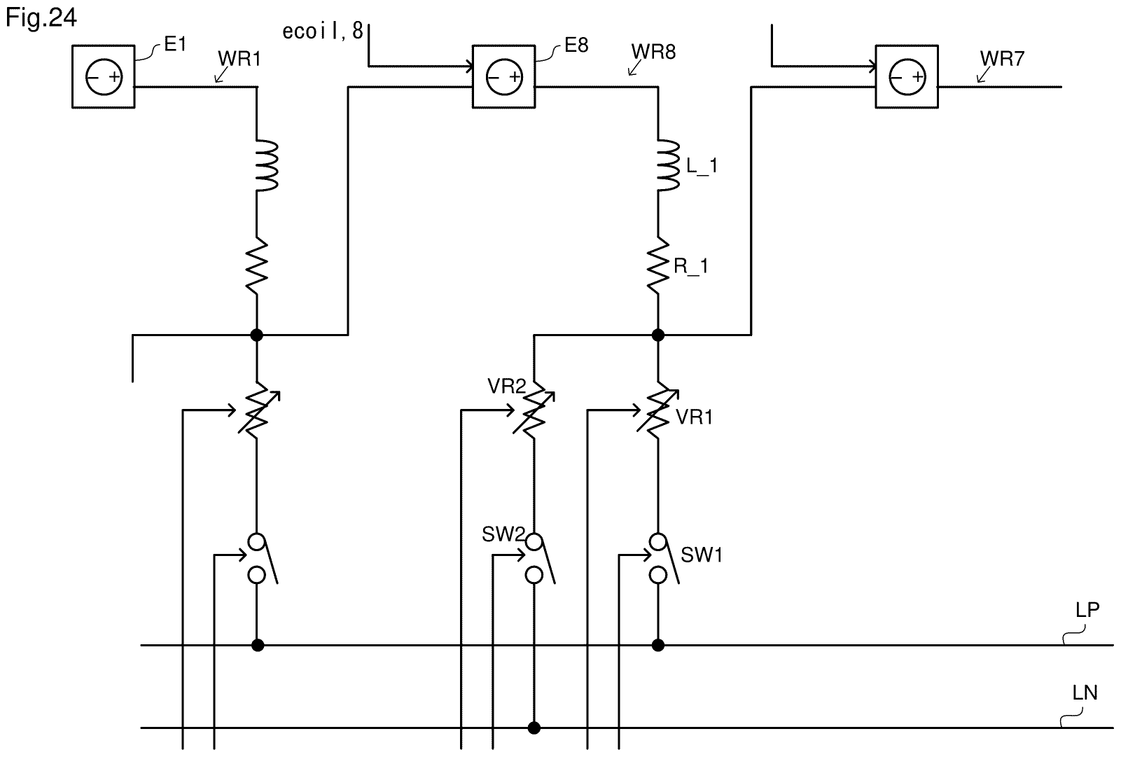

The induced electromotive voltage generation section 2A generates the induced electromotive voltage of each of the wirings WR on the basis of the mechanical angle θm. Here, as an example of the wiring circuit model section 2B, a partial structure thereof is illustrated in FIG. 24. Here, considering that the number of polar pairs p is two, the modeling is performed for eight wirings WR, i.e., a half of 16 wirings WR that is the actual total number. Note that it may be possible to perform the modeling for the actual total number of wirings WR.

Therefore, as illustrated in FIG. 24, the wiring WR is modeled using the wirings WR1 to WR8, and the brush BR is modeled using a pair of the positive electrode brush and the negative electrode brush. The induced electromotive voltage e_{coil, No.} generated by the induced electromotive voltage generation section 2A is output from a voltage source E inserted in the wiring WR of the corresponding wiring number. FIG. 24 illustrates that an induced electromotive voltage e_{coil, 8} is output from a voltage source E8 in the wiring WR8.

In addition, as illustrated in FIG. 24, the wiring circuit model section 2B is modeled so that switches SW1 and SW2 and variable resistors VR1 and VR2 are disposed for each wiring WR. Specifically, in the wiring WR, the inductor L_1 and the resistance R_1 are connected in series. One terminal of the resistance R_1 (opposite to the terminal to which the inductor L_1 is connected) is connected to one terminal of the variable resistor VR1, and the switch SW1 is connected between the other terminal of the variable resistor VR1 and a positive electrode line LP. The positive electrode line LP is connected to the positive electrode brush. In addition, one terminal of the resistance R_1 is also connected to one terminal of the variable resistor VR2, and the switch SW2 is connected between the other terminal of the variable resistor VR2 and a negative electrode line LN. The negative electrode line LN is connected to the negative electrode brush.

When the commutator piece CM that is connected to the lead wire of the wiring WR contacts the positive electrode brush, the switch SW1 is turned on, and a resistance of the variable resistor VR1 is set to the contact resistance. When the commutator piece CM that is connected to the lead wire of the wiring WR contacts the negative electrode brush, the switch SW2 is turned on, and a resistance of the variable resistor VR2 is set to the contact resistance. Note that if the commutator piece CM does not contact the positive electrode brush or the negative electrode brush, the switch SW1 or SW2 is turned off. Note that both the switches SW1 and SW2 may be turned off.

The switch signal generation section 2E illustrated in FIG. 23 determines ON/OFF of the switch SW1, SW2 for each of the wirings WR, on the basis of the mechanical angle θm, so as to generate a switch signal. On the basis of the generated switch signal, the switch SW1, SW2 is turned on or off. In addition, the ripple angle conversion section 2C converts the mechanical angle θm into the ripple angle θr. The contact resistance generation section 2D generates the contact resistance between the commutator piece CM and the brush BR on the basis of the ripple angle θr. The generated contact resistance is set as a resistance of the variable resistor VR1, VR2.

In the state where the induced electromotive voltage by the voltage source E, ON/OFF states of the switches SW1 and SW2, and resistance values of the variable resistors VR1 and VR2 are determined, the wiring circuit model section 2B calculates and outputs the motor terminal current im when the input voltage Vin is input. Note that in the above case where the modeling is performed with eight wirings WR considering that the number of polar pairs is two, the motor terminal current im is reduced by half, and hence the calculated motor terminal current im is input to an amplifier with double gain, which outputs to the motion equation section 2111A.

### <Simulation Result>

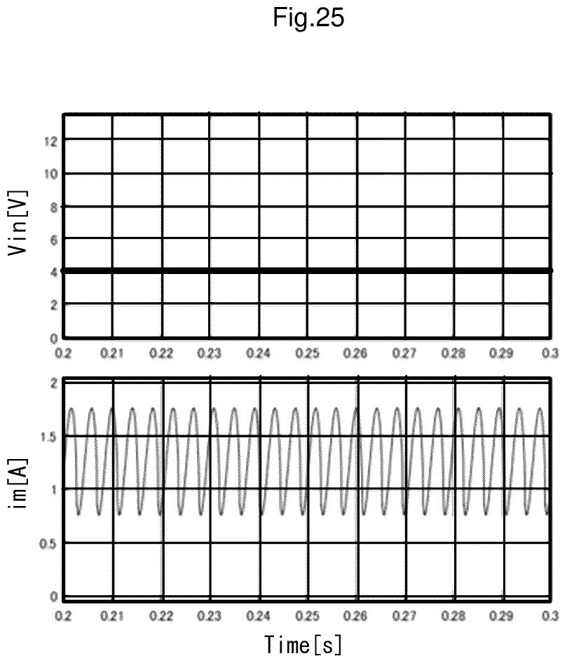

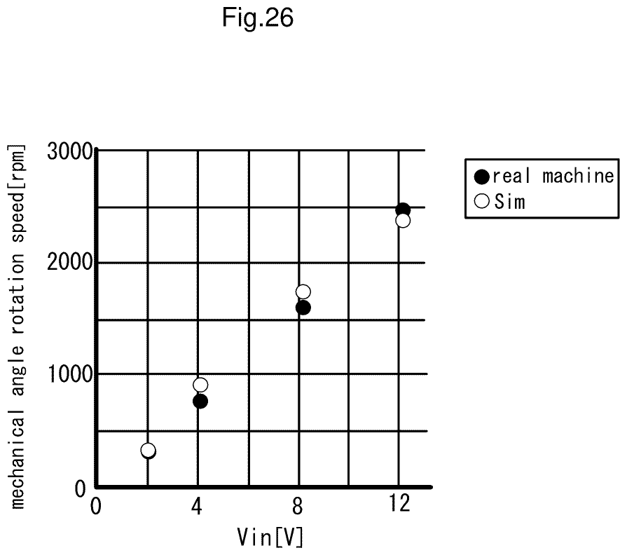

FIG. 25 is a diagram illustrating an example of a result when the simulation according to the present disclosure is performed. When the input voltage Vin is applied, the motor terminal current im has a ripple waveform in the same manner as the real machine. In addition, FIG. 26 is a diagram illustrating an example of comparison between the real machine and simulation, about a relationship between the input voltage Vin and a mechanical angle rotation speed. In this way, the phenomenon of increasing the mechanical angle rotation speed along with an increase of the input voltage Vin is reconstructed by simulation, similarly to the real machine. Using the simulation according to the present disclosure, simulation time can be reduced by largely reducing calculation amount.

### <Abnormal State Model>

As illustrated in FIG. 4, the motor model 211 includes an abnormal state model 211A. The abnormal state model 211A includes a bearing lubrication deficiency model 2112 and a bearing damage model 2113. An abnormality of the bearing 20E is modeled as an abnormal state because of the following reason. The bearing 20E is a mechanical element for supporting the shaft 20C, and is independent of other mechanical elements in the motor or a load. In other words, an abnormal state of the bearing 20E can be handled independently of other abnormal states. In addition, bearings are disposed in any type of motor or for any type of load, and the abnormal state model of bearing can be utilized without depending on a type of motor or a type of load.

Abnormalities of a bearing can be classified broadly into two types, i.e., lubrication deficiency and damage, and hence the bearing lubrication deficiency model 2112 and the bearing damage model 2113 are modeled. The bearing 20E is connected to the shaft 20C via friction and a normal force in mechanical way. Therefore, the abnormal state model 211A is modeled as a model that outputs a friction torque as a difference (deviation amount) between the normal state and the abnormal state, and the normal force due to abnormality.

### <Bearing Lubrication Deficiency Model>

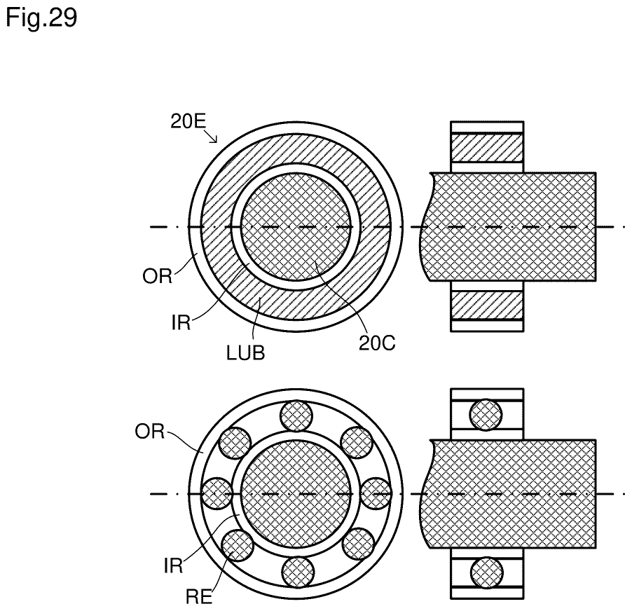

FIG. 29 illustrates a front view and a cross-sectional side view of the bearing 20E and the shaft 20C. The bearing 20E includes an outer ring OR and an inner ring IR. The shaft 20C is fixed inside the inner ring IR. Lubricant LUB is applied between the outer ring OR and the inner ring IR. In this way, the inner ring IR and the shaft 20C rotate with respect to the outer ring OR that is at rest. Note that FIG. 29 illustrates an example of a case where the bearing is a rolling bearing, but the bearing may be a slide bearing.

Lubrication deficiency of the bearing 20E may be overall deficiency or local deficiency, and it depends on viscosity of the lubricant or a degree of fluidity contribution. On the basis of the above discussion, the lubrication deficiency can be expressed mathematically as a superposition of a mode depending on a mechanical angle and a rotation speed of the rotation shaft, and a mode depending only on the rotation speed. The mode depending on a mechanical angle and a rotation speed of the rotation shaft means a mode related to a mechanical variation or fluctuation in one turn of the shaft. For instance, it is related to a surface state, a size variation, a deviation from perfect circle, an engagement degree, a foreign object adhesion point, a damaged point, a radial load, and the like. The mode depending only on the rotation speed means a mode related to kinematic viscosity between fluid (such as air, lubricating oil, or grease) and the surface when they are sliding against each other. In this way, the friction torque due to lubrication deficiency (deviation from the normal state) is expressed by the following equation (3):

$${T}_{lubrication} = {B}_{lub \_ cof 1} \cdot {ω}_{m}^{{B}_{lub \_ index 1}} + {B}_{lub \_ cof {2}_{}} \cdot f ( {θ}_{m} ) \cdot {ω}_{m}^{{B}_{lub \_ index 2}} \qquad ( 3 )$$

where B_{lub_cof1} and B_{lub_cof2} are constant coefficients, and B_{lub_index1} and B_{lub_index2} are rotation speed indexes. However, f(θm) is a function of the mechanical angle θm. In accordance with a value of a selection switch SW_B_{lub_cof2} (integer 1 to 7), f(θm) is switched as following equations, where theta_m equals θm.

$$1 : f ( theta\_m ) = 1 \vert sin ( 0.5 * theta\_m ) \vert \\ 2 : f ( theta\_m ) = \{ 1 \vert sin ( 0 . {5}^{*} theta\_m ) \vert \} \hat{} 2 \\ 3 : f ( theta\_m ) = \{ 1 \vert sin ( 0.5 * theta\_m ) \vert \} \hat{} 4 \\ 4 : f ( theta\_m ) = \vert sin ( {0.5}^{*} theta\_m ) \vert \\ 5 : f ( theta\_m ) = \{ \vert sin ( 0 . {5}^{*} theta\_m ) \vert \} \hat{} 2 \\ 6 : f ( theta\_m ) = sin ( theta\_m ) \\ 7 : f ( theta\_m ) = 0$$

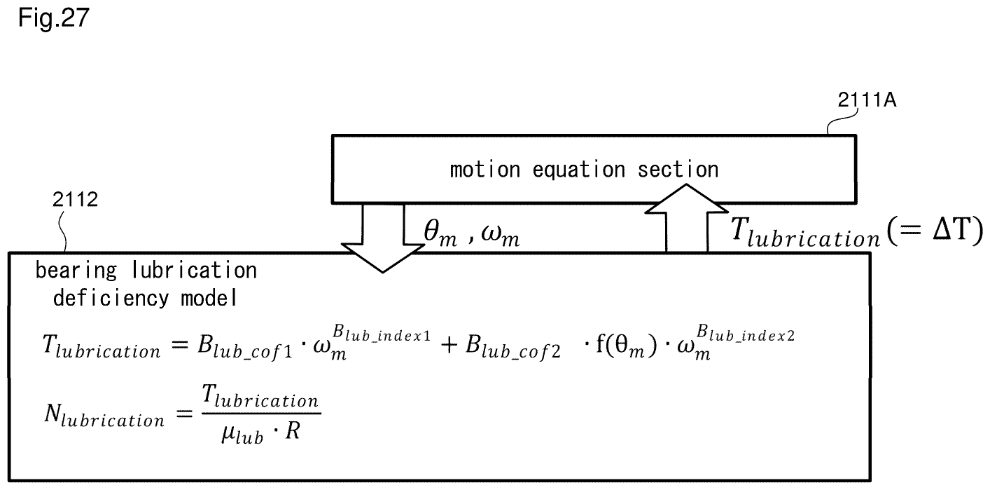

As illustrated in FIG. 27, the mechanical angle θm and the mechanical angular velocity ωm output from the motion equation section 2111A are input to the above equation (3), and a friction torque T_{lubrication} is calculated. The calculated friction torque T_{lubrication} is input to the motion equation section 2111A, as a loss torque component ΔT due to the abnormal state in the above equation (1). The progress of the abnormal state (i.e., deterioration) is expressed by increasing or decreasing the parameter in the above equation (3) as a time function.

In addition, in the bearing lubrication deficiency model 2112, the normal force due to an abnormality is calculated by the following equation (4):

$${N}_{lubrication} = \frac{{T}_{lubrication}}{{μ}_{lub} \cdot R} \qquad ( 4 )$$

where μ_{lub} is a friction coefficient, and R is a radius of the shaft 20C.

In other words, using the friction torque calculated by the above equation (3), the normal force is calculated. The normal force calculated in this way is input as a vibromotive force to a vibration model of a support system described later.

### <Bearing Damage Model>

As illustrated in FIG. 29, the bearing 20E includes rolling elements RE disposed between the outer ring OR and the inner ring IR. A plurality of the rolling elements RE are disposed in the circumferential direction. Note that the lubricant LUB and the rolling elements RE are illustrated separately in FIG. 29 for convenience sake.

The bearing damages are classified into modes depending on which of the mechanical elements constituting the bearing has generated the damage. Specifically, they are classified into three modes of outer ring damage, inner ring damage, and rolling element damage.

The rolling element RE rotates and revolves to move in the circumferential direction. In the case of the outer ring damage, an impulsive force (hereinafter referred to as a shock pulse) occurs every time when the rolling element RE slides against the damaged point. The shock pulse acts on the shaft 20C as the normal force and the friction torque. In this way, in the case of the outer ring damage, every time when revolution angle θrevolution of the rolling element RE satisfy the following equation (A), the normal force expressed by the following equation (5) occurs:

$$\frac{2 π n}{Z} \leq {θ}_{revolution} \leq \frac{2 π n}{Z} + {P}_{width} \qquad ( A )$$

$${N}_{bearing \_ damage} = {P}_{hight} \qquad ( 5 )$$

where Z is the number of rolling elements, P_{hight} is height of the shock pulse, P_{width} is width of the shock pulse, and n is an integer starting from 0 (n=0, 1, 2, . . . ).

In addition, in the case of the inner ring damage, a shock pulse occurs every time when the rolling element RE slides against the damaged point. In this way, in the case of the inner ring damage, every time when the revolution angle θrevolution of the rolling element RE satisfies the following inequality (B), the normal force expressed by the above equation (5) occurs.

$$\frac{2 π n}{Z} \leq {θ}_{m} - {θ}_{revolution} \leq \frac{2 π n}{Z} + {P}_{width} \qquad ( B )$$

In addition, in the case of the rolling element damage, a shock pulse occurs every time when the outer ring or the inner ring slides against the damaged point of the rolling element RE that rotates. In this way, in the case of the rolling element damage, every time when a rotation angle θᵣₒₜₐₜᵢₒₙ of the rolling element RE satisfies the following inequality (C), the normal force expressed by the above equation (5) occurs.

$$π n \leq {θ}_{rotatioin} \leq π n + {P}_{width} \qquad ( C )$$

On the basis of the normal force N_{bearing_damage} due to the damage as described above, the friction torque due to the damage is expressed by the following equation (6):

$${T}_{bearing\_damage} = {μ}_{bearing} \cdot {N}_{bearing\_damage} \cdot R \qquad ( 6 )$$

where μ_{bearing} is the friction coefficient, and R is the radius of the shaft 20C.

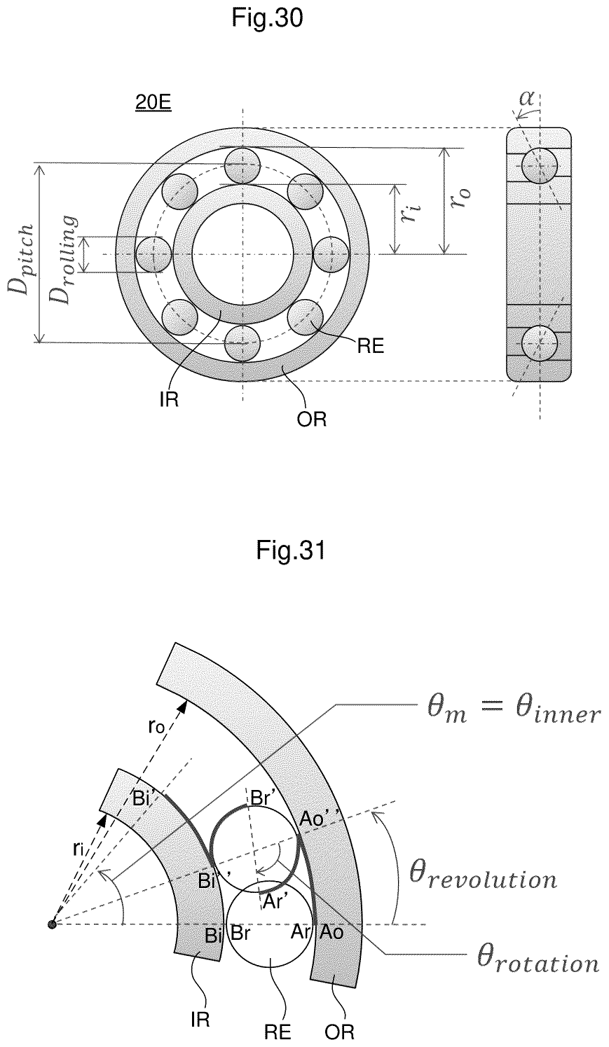

The revolution angle θᵣₑᵥₒₗᵤₜᵢₒₙ and the rotation angle θᵣₒₜₐₜᵢₒₙ are calculated by the following equations on the basis of the mechanical angle θm:

$${θ}_{inner} = {θ}_{m}$$

$${θ}_{revolution} = \frac{1}{2} \cdot ( 1 - \frac{{D}_{rolling}}{{D}_{pitch}} cos α ) \cdot {θ}_{m}$$

$${θ}_{rotation} = \frac{1}{2} \cdot \frac{{D}_{pitch}}{{D}_{rolling}} \cdot \{ 1 - {( \frac{{D}_{rolling}}{{D}_{pitch}} cos α )}^{2} \} \cdot {θ}_{m}$$

where, θᵢₙₙₑᵣ is a rotation angle of the inner ring, D_{pitch} is a diameter of a pitch circle of the bearing, D_{rolling} is a diameter of the rolling element, and a is a contact angle. These parameters are illustrated in FIG. 30. Note that FIG. 30 also illustrates an inner ring orbital radius rᵢ, and an outer ring orbital radius rₒ.

Here, derivation of the above equations is described with reference to FIG. 31. FIG. 31 illustrates the revolution angle θᵣₑᵥₒₗᵤₜᵢₒₙ and the rotation angle θᵣₒₜₐₜᵢₒₙ of the rolling element RE when the inner ring IR rotates by the angle θᵢₙₙₑᵣ (=θm). Points Ar and Br indicate contact points of the rolling element RE with the outer ring OR and the inner ring IR, respectively. Points Ar′ and Br′ respectively indicate moved points of the points Ar and Br when the rolling element RE revolves. In this case, contact points of the outer ring OR and the inner ring IR change from Ao to Ao″ and Bi to Bi″, respectively, and it is supposed that the contact point Bi has moved to Bi′.

Length Ar′Ao″ equals length AoAo″, and hence the following equation (D) holds.

$${r}_{r} {θ}_{rotation} = {r}_{o} {θ}_{revolution} \qquad ( D )$$

On the other hand, length Br′Bi″ equals length Bi′Bi″, and hence the following equation (E) holds.

$${r}_{r} {θ}_{rotation} = {r}_{i} ( θ m - {θ}_{revolution} ) \qquad ( E )$$

From the above equations (D) and (E), the following equations hold.

$${r}_{o} {θ}_{revolution} = {r}_{i} θ m - {r}_{i} {θ}_{revolution}$$

$${θ}_{revolution} = ( {r}_{i} / ( {r}_{o} + {r}_{i} ) ) {θ}_{m}$$

Here, the following equations hold.

$${r}_{i} = ( {D}_{pitch} - {D}_{rolling} \times cos α ) / 2$$

$${r}_{o} = ( {D}_{pitch} + {D}_{rolling} \times cos α ) / 2$$

Hence, following equation holds.

$${θ}_{revolution} = 1 / 2 \times ( 1 - {D}_{rolling} / {D}_{pitch} \times cos α ) \times θ m$$

On the other hand, from the above equation (D), the following equation holds.

$${θ}_{rotation} = {r}_{o} / {r}_{r} \times {θ}_{revolution}$$

Here, because θᵣₑᵥₒₗᵤₜᵢₒₙ equals ½×(1−D_{rolling}/D_{pitch}×cos α)×θm, and rᵣ equals D_{rolling}/2 as described above, the following equation holds.

$${θ}_{rotation} = 1 / 2 \times {D}_{pitch} / {D}_{rolling} \times ( 1 - {( {D}_{rolling} / {D}_{pitch} \times cos α )}^{2} ) \times θ m$$

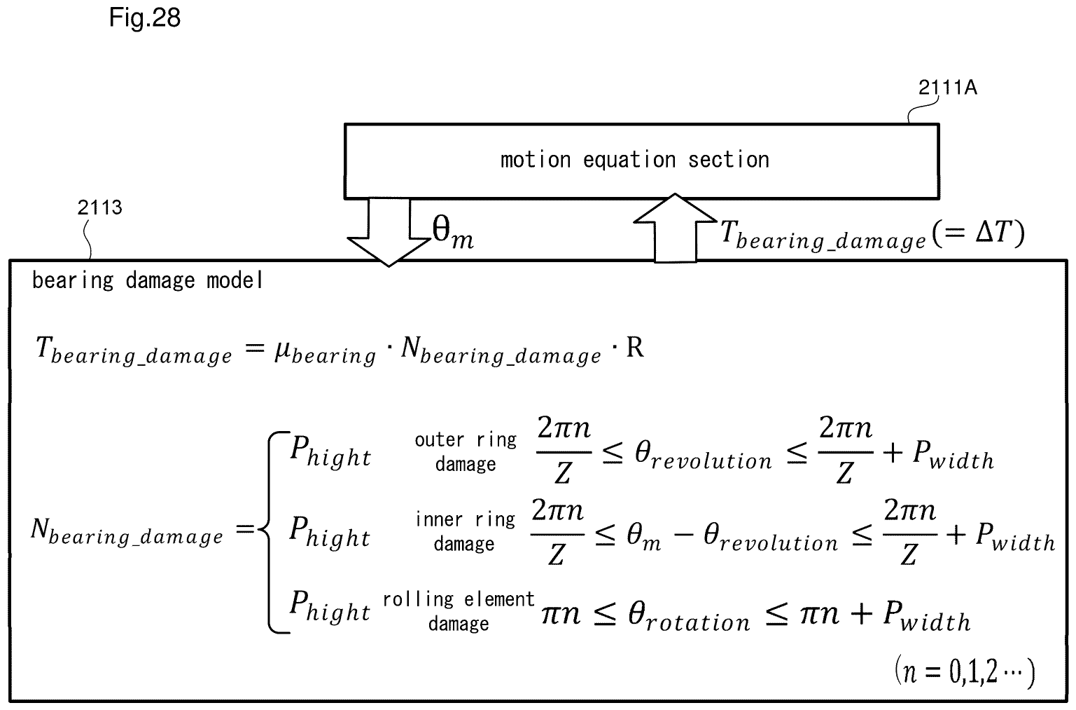

As illustrated in FIG. 28, the mechanical angle θm output from the motion equation section 2111A is input to the bearing damage model 2113. The friction torque T_{bearing_damage} calculated in the bearing damage model 2113 is input to the motion equation section 2111A, as the loss torque component ΔT due to the abnormal state in the above equation (1). The progress of the abnormal state (i.e., deterioration) is expressed by increasing or decreasing the height P_{hight} and the width P_{width} of the shock pulse as a time function. Note that the normal force N_{bearing_damage} is input to a support system vibration model described later.

### <Relationship Between Abnormal State Model and Motor Physical Model>

As illustrated in FIG. 4, signals are communicated between the motor physical model 2111 (the motion equation section) and the bearing lubrication deficiency model 2112, as well as between the motor physical model 2111 and the bearing damage model 2113. However, signals are not communicated between the bearing lubrication deficiency model 2112 and the bearing damage model 2113. This is because transition from the normal state to the abnormal state is performed to one abnormal state first, and then to a composite abnormal state when the abnormality proceeds, as known from various findings such as statistics. As a model for early detection of signs of abnormality, it is sufficient if an earliest phase of transition to one abnormal state can be expressed.

### <Vibration Model of Support System>

As illustrated in FIG. 4, the motor model 211 includes a support system vibration model 2114. First, the support system is defined as all mechanical elements constituting the motor 20 including the case 20A. The mount 201 (FIG. 3) is not the support system but is at rest. The coordinate system handling vibration of the support system is a static coordinate system as illustrated in FIG. 3. The coordinate axes of the static coordinate system are defined as described above. The reason why the coordinate axes are defined in this way is because the motor 20 generally has anisotropy of stiffness between the direction perpendicular to the installation plane and the horizontal direction.

Vibration of the support system is generated when a force due to an abnormality (vibromotive force) is applied to the support system. In lubrication deficiency and damage deficiency of the bearing 20E described above, the normal force due to an abnormality becomes the vibromotive force. Note that in the case of bearing abnormality, the vibromotive force is a vector in XY plane.

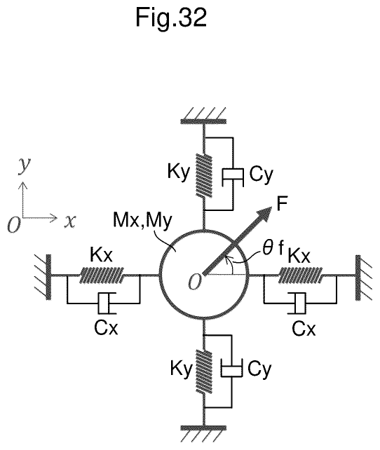

How the support system is vibrated is determined by combination of stiffness (spring constant) and damping characteristic of individual mechanical elements constituting the support system. The support system vibration model is assumed to be a system constituted of springs Kx and Ky, dampers Cx and Cy, and a particle having a mass M, as illustrated in FIG. 32. The entire motor 20 including the case 20A and all loads connected to the shaft 20C are regarded as the particle having the mass M. The spring Kx and the damper Cx are connected in parallel to each other on each side of the particle in an X direction. The spring Ky and the damper Cy are connected in parallel to each other on each side of the particle in a Y direction.

In such the support system, a translational equation of motion is expressed by the following equation (7). Note that it is necessary to make the translational equation of motion for each vibration measurement point of a vibration sensor (for each position of the vibration sensor). This is because that parameters M, k, and c can change depending on the vibration measurement point.

$${M}_{x} \frac{{d}^{2} x}{{dt}^{2}} = - {c}_{x} \frac{dx}{dt} - {k}_{x} x + F cos {θ}_{f} , \qquad ( 7 )$$

$${M}_{y} \frac{{d}^{2} y}{{dt}^{2}} = - {c}_{y} \frac{dy}{dt} - {k}_{y} y + F sin {θ}_{f}$$

where kₓ is a spring constant of the spring Kx, k_{y} is a spring constant of the spring Ky, cₓ is a damping coefficient of the damper Cx, cy is a damping coefficient of the damper Cy, F is an external force acting on the particle, and θf is an angle from the X-axis, which indicates a direction of the external force F.

It is not practical to repeat and combine stiffness and damping characteristic of each mechanical element constituting the support system, and hence stiffness and damping characteristic of the entire support system are approximated, so that each approximate value can be set to a parameter as a typical value. Note that it may be possible to make the equation of motion for each of X-axis, Y-axis, and Z-axis. In addition, for example, when measuring vibration in an axis inclined by 45 degrees on XY plane, it is sufficient to combine X-axis vibration and Y-axis vibration.

As described above, the normal force N_{lubrication} (the above equation (4)) output from the bearing lubrication deficiency model 2112, or the normal force N_{bearing_damage} (the above equation (5)) output from the bearing damage model 2113 is input to the support system vibration model 2114, as an external force F. By the equation of motion (the above equation (7)) in the support system vibration model 2114, time-series data of displacement in the X direction and displacement in the Y direction are output. Note that speed data can be obtained by first derivative of the displacement data, and acceleration data can be obtained by first derivative of the speed data.

Note that no signal is input from the support system vibration model 2114 to the abnormal state model 211A (FIG. 4). This is because that when a force is applied, vibration occurs as a result, which is handled.

### <Operation of Motor Model>

When performing simulation, the model arithmetic unit 3 performs arithmetic processing of the motor model 211. In this case, while signals are communicated between the motion equation section 2111A and the abnormal state model 211A, numerical calculation of the motor physical model 2111 (the motion equation section 2111A and the wiring circuit section 2111B) is performed, and time-series data of the motor terminal current im are output from the wiring circuit section 2111B. On the other hand, the support system vibration model 2114 performs numerical calculation while receiving the input from the abnormal state model 211A, and outputs time-series data of the displacement in the X direction, the displacement in the Y direction, the acceleration in the X direction, and the acceleration in the Y direction.

In this way, the motor model 211 outputs time-series data of the motor terminal current im, the displacement in the X direction, the displacement in the Y direction, the acceleration in the X direction, and the acceleration in the Y direction, as physical signal waveform data. By setting the abnormal state model 211A to abnormal state, the physical signal waveform in the abnormal state can be virtually generated.

When generating signal waveform data of a motor abnormal state, if a model based on a finite element method is used, the simulation speed is very slow. In addition, if a model in which frequency component noise is added with reference to experiment data, relationships between individual physical signals may have inconsistency. Therefore, using the motor model 211 according to this embodiment, it is possible to generate the physical signal waveform data of abnormal state with necessary accuracy and appropriate simulation speed. In this case, there is no inconsistency between individual physical signals.

Note that it is also possible to virtually generate the physical signal waveform of the normal state by setting the abnormal state model 211A to the normal state. In this case, the coefficient B_{lub_cof1} and the B_{lub_cof2} in the above equation (3) are each set to zero in the bearing lubrication deficiency model 2112, while the height P_{hight} of the shock pulse in the above equation (5) is set to zero in the bearing damage model 2113.

### <Sensor Model>

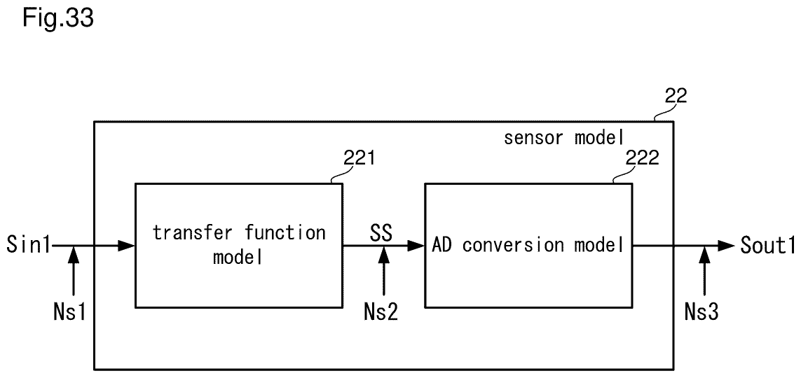

Next, the sensor model 22 is described. FIG. 33 is a diagram illustrating a structural example of the sensor model 22. The sensor model 22 includes a transfer function model 221 and an AD conversion model 222. Note that the sensor model 22 includes the transfer function model 221 and the AD conversion model 222 for each type of the sensor. The types of the sensor include, for example, a current sensor and a vibration sensor. In this way, it is possible to select a type of the sensor as described later.

The transfer function model 221 receives an input signal Sin1 and outputs a sense signal SS as an analog signal. The sense signal SS is AD-converted by the AD conversion model 222, and an output signal (sense signal) Sout1 is output as a digital signal. The transfer function model 221 includes a filter. As described later, a type of the filter and characteristic of the filter (such as a cut-off frequency) can be set. In addition, characteristic of the AD conversion model 222 (such as a sampling speed) can also be set.

The physical signal waveform data output from the motor model 211 (or data based on the physical signal waveform data) is input to the sensor model 22 as the input signal Sin1. If the physical signal waveform data is the motor terminal current im, it is input to the sensor model 22 as the current sensor. If the physical signal waveform data (or data based on the physical signal waveform data) is the displacement in the X direction, the displacement in the Y direction, the acceleration in the X direction, and the acceleration in the Y direction, it is input to the sensor model 22 as the vibration sensor.

Note that as illustrated in FIG. 33, noises Ns1, Ns2, and Ns3 can be input respectively in a former part of the transfer function model 221, between the transfer function model 221 and the AD conversion model 222, and in a latter part of the AD conversion model. A type of the noise, such as normal distribution noise, uniform distribution noise, or the like can be specified, and the parameter such as the average value, a variance (standard deviation), or the like can be set in accordance with the type.

### <Machine Learning Model>

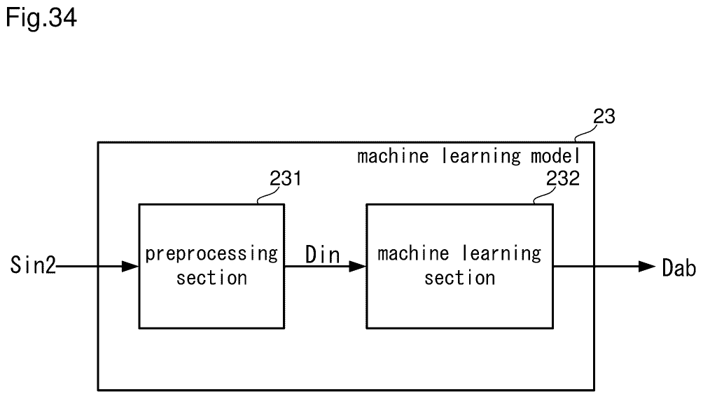

Next, the machine learning model 23 is described. FIG. 34 is a diagram illustrating a structural example of the machine learning model 23. The machine learning model 23 includes a preprocessing section 231 and a machine learning section 232.

The preprocessing section 231 performs preprocessing on an input signal Sin2. The preprocessing includes, envelope processing, window function processing, and fast Fourier transform (FFT) processing. As described later, it is possible to select presence or absence of execution of the envelope processing, the window function processing, or the FFT processing. As patterns, it is possible to select execution of only the window function processing, execution of only the envelope processing, execution of only the FFT processing, execution of the window function processing and the FFT processing, execution of the envelope processing and the FFT processing, or execution of the envelope processing, the window function processing, and the FFT processing. Note that without limiting to the FFT processing, it is possible to use frequency analysis processing such as wavelet transformation, for example.

In addition, in the preprocessing section 231, a normalization process is also performed for the machine learning section 232 to perform appropriate learning. The normalization process is a process of multiplying data by a normalization coefficient, so as to keep the data within the range of approximately 0 to 1 (or −1 to +1). If the input data has a value outside a predetermined range, learning is not performed, or the value is regarded as a saturated value to perform learning, and therefore it is necessary to perform the normalization process as the preprocess in order to learn all data.

If presence of the preprocess is selected, at least one of the window function processing and the FFT processing is performed on the input signal Sin2, and then the normalization process is performed, so as to make an input data Din as an input to the machine learning section 232. In addition, if absence of the preprocess is selected, the normalization process is performed on the input signal Sin2, so as to make the input data Din.

The machine learning section 232 performs learning and inference on the input data Din.

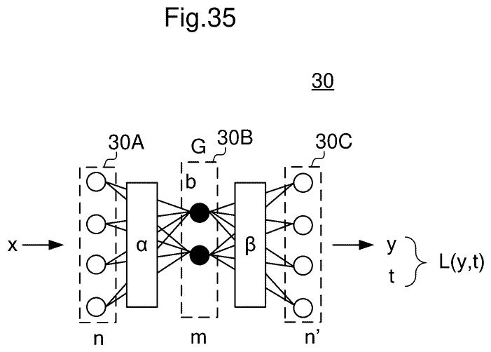

As an AI model that is used in the machine learning section 232, for example, a three-layer neural network 30 illustrated in FIG. 35 is used.

As illustrated in FIG. 35, the three-layer neural network 30 is an AI model including an input layer 30A, a hidden layer 30B, and an output layer 30C. In general, in the three-layer neural network 30, n′-dimensional inference result y∈R^{k×n′} of n-dimensional input data x∈R^{k×n} having a batch size of k is obtained as y=G(x×α+b)β. Here, α∈R^{n×m} is a weight for combining the input layer 30A and the hidden layer 30B, and β∈R^{n×m′} is a weight for combining the hidden layer 30B and the output layer 30C. In addition, b∈R^{m} is a bias of the hidden layer 30B, and G is an activation function of the hidden layer 30B.

This embodiment uses an algorithm that can learn the three-layer neural network 30 sequentially with any batch size. If the i-th learning data {xᵢ∈R^{ki×n}, tᵢ∈R^{ki×n′}} having a batch size of ki is obtained, it is necessary to determine βᵢ that minimizes an error expressed by the following expression (8).

$$‖ [ \begin{matrix}{H}_{0} \\ ⋮ \\ {H}_{i}\end{matrix} ] {β}_{i} - [ \begin{matrix}{t}_{0} \\ ⋮ \\ {t}_{i}\end{matrix} ] ‖ \qquad ( 8 )$$

Note that i-th hidden layer matrix Hi equals to G (xᵢ×α+b). In addition, tis teaching data corresponding to the inference result y.

An optimized weight βᵢ is calculated by the following equations (9).

$${P}_{i} = {P}_{i - 1} - {P}_{i - 1} {{Hi}^{T} ( I + {H}_{i} {P}_{i - 1} {Hi}^{T} )}^{- 1} {H}_{i} {P}_{i - 1} \qquad ( 9 )$$

$${β}_{i} = {β}_{i - 1} + {P}_{i} {H}_{i}^{T} ( {t}_{i} - {H}_{i} {β}_{i - 1} )$$

Here, P₀ and B₀ are obtained from the following equations (10).

$${P}_{0} = {( {H}_{0}^{T} {H}_{0} )}^{- 1} \qquad ( 10 )$$

$${β}_{0} = {P}_{0} {H}_{0}^{T} {t}_{0}$$

A learning algorithm is as follows.
(1) Initialize values of the weight α and the bias b using random number.
(2) Calculate H₀ with respect to x₀, and calculate P₀ and β₀.
(3) Calculate Pᵢ and βᵢ sequentially every time when the i-th learning data having a batch size of kᵢ is obtained. Note that it is possible not to use the equation for calculating β₀ in the equations (10) but to set the value initialized by random number to β₀.

In addition, in this embodiment, learning using an autoencoder is performed. The autoencoder uses input data as teaching data as it is, and learning is performed so that input data can be reconstructed as inference result. In other words, in the above case, learning is performed as t=x. The autoencoder is one type of learning algorithm without teacher because it is not necessary to prepare teaching data separately.

According to the AI model in the machine learning section 232 described above, learning can be performed by the arithmetic device at a microcomputer level in an edge device. In particular, the bottleneck of calculation in the above equation (9) is (I+HᵢPᵢ₋₁Hi^{T})⁻¹, and a matrix size of (I+HᵢPᵢ₋₁Hi^{T}) is k×k. Hence, if k=1, inverse matrix calculation can be replaced by reciprocal calculation. Thus, by fixing the batch size as k=1, the calculation can be easily performed by the arithmetic device at a microcomputer level. In other words, when introducing such on-device learning to abnormality detection of a motor, it is possible to check effects of the abnormality detection by simulation. Note that the input data x is time-series data in the case of absence of the FFT processing in the preprocessing section 231, while it is frequency domain data in the case of presence of the FFT processing.

In the machine learning section 232, the abnormality degree is calculated by a loss function L(y, t) indicating an error between the inference result y and the teaching data t. As the loss function, a mean absolute error (MAE) or a mean squared error (MSE) is used, for example. If the loss function is MAE, the loss function L is expressed by the following equation (11).

$$L ( y , t ) = \frac{1}{{n}^{′}} \sum \vert y - t \vert \qquad ( 11 )$$

In contrast, if the loss function is MSE, the loss function L is expressed by the following equation (12).

$$L ( y , t ) = \frac{1}{{n}^{′}} \sum {\vert y - t \vert}^{2} \qquad ( 12 )$$

As the autoencoder is used to perform learning, the error is calculated as the loss function L(y, t)=L(y, x), and the calculated error is regarded as the abnormality degree. The calculated abnormality degree is output from the machine learning section 232 as abnormality degree data Dab.

Note that a forgetting rate can be set in this embodiment. The forgetting rate is a parameter indicating a degree of forgetting learning results. As a method that doesn't reflect learning results, for example, there is a method of using learning results in the past, a method of initializing learning results, or the like.

### <Abnormality Determination Model>

Next, the abnormality determination model 24 is described. Abnormality determination is performed on the basis of the abnormality degree data Dab output from the machine learning model 23. For instance, the abnormality determination model 24 compares the abnormality degree with one threshold value, so as to determine abnormality or normality. In addition, for example, the abnormality determination model 24 may compare the abnormality degree with a plurality of threshold values, so as to determine an abnormality level in a stepwise manner. As described later, it is possible to select this method of abnormality determination. In addition, the abnormality determination model 24 may perform integration, averaging, or other processing of the abnormality degree before comparing with the threshold value.

### <Simulation Setting GUI>

Next described is a graphical user interface (GUI) that enables to set simulation conditions in the simulation apparatus 1 according to this embodiment. Various setting screen examples described below are displayed on the display unit 7 by the display control unit 5 (FIG. 2). Selecting and setting on the setting screen, and switching of screens are performed on the basis of the input from the operation input unit 6. Contents of setting performed on various setting screens are set by the model setting unit 4.

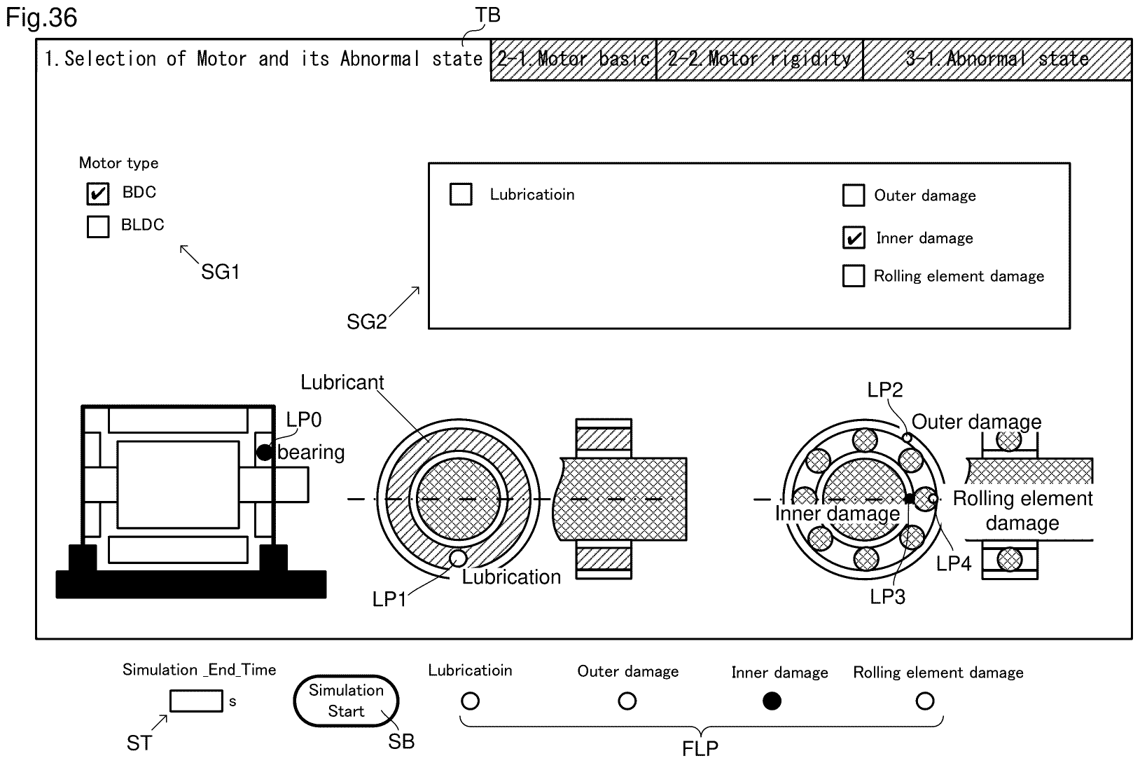

FIG. 36 is a diagram illustrating a setting screen for motor type and abnormal state (hereinafter referred to as a first setting screen). Along the upper side of the first setting screen, tabs TB are arranged and displayed in the left and right direction. By selecting the tab TB, the setting screens are switched. In addition, in the first setting screen, a motor type selection section SG1 and an abnormal state selection section SG2 are displayed.

In the motor type selection section SG1, motors as selection candidates are displayed, and the motor can be selected. In FIG. 36, the BDC motor and the BLDC motor are displayed as motor types, and the BDC motor is selected, as an example.

In the abnormal state selection section SG2, an abnormal state of the motor can be selected. Specifically, bearing lubrication deficiency, bearing outer ring damage, bearing inner ring damage, and bearing rolling element damage are displayed as selection candidates, and one of them can be selected as the abnormal state. In FIG. 36, the inner ring damage is selected as an example.

In addition, in the first setting screen, lamp LP0 is displayed, which indicates the mechanical element corresponding to a selectable abnormal state. The lamp LP0 is displayed in a display indicating the entire structure of the motor and can be turned off or on. The lamp LP0 of the mechanical element corresponding to the selected abnormal state is turned on. In FIG. 36, because the inner ring damage is selected as an example, the lamp LP0 of the bearing as the corresponding mechanical element is turned on. By such the lamp LP0, the mechanical element corresponding to the abnormal state as a simulation target can be easily checked.

In addition, in the first setting screen, lamps LP1 to LP4 are displayed, which indicate occurrence points of selectable abnormal states. In FIG. 36, the lamp LP1 indicating bearing lubricant, the lamp LP2 indicating outer ring, the lamp LP3 indicating the inner ring, and the lamp LP4 indicating the rolling element are displayed as an example. LP1 corresponds to the bearing lubrication deficiency, LP2 corresponds to the outer ring damage, LP3 corresponds to the inner ring damage, and LP4 corresponds to the rolling element damage. LP1 to LP4 can be turned off or on. The lamp LP1 to LP4 corresponding to the selected abnormal state is turned on. In the example of FIG. 36, the inner ring damage is selected, and the lamp LP3 is turned on. By such the lamps LP1 to LP4, the occurrence point of the abnormal state as the simulation target can be easily checked.

In addition, on the lower side of the first setting screen, a simulation time setting section ST, a simulation start button SB, and abnormal state lamps FLP are displayed. Note that these displays are commonly displayed even when the setting screen is switched. In the simulation time setting section ST, the simulation time can be set. After the simulation starts, when the time set in the simulation time setting section ST elapses, the simulation is stopped. Note that if the time is set so that the simulation stops before inference start timing described later, the simulation is stopped before the inference starts.

By pressing the simulation start button SB, the simulation can be started. The abnormal state lamps FLP are lamps corresponding to the selectable abnormal states, and can be turned off or on. In FIG. 36, as the abnormal state lamps FLP, lamps of the bearing lubrication deficiency, the outer ring damage, the inner ring damage, and the rolling element damage are arranged and displayed in the left and right direction, as an example. In the example of FIG. 36, the inner ring damage is selected, and the abnormal state lamp FLP of the inner ring damage is turned on.

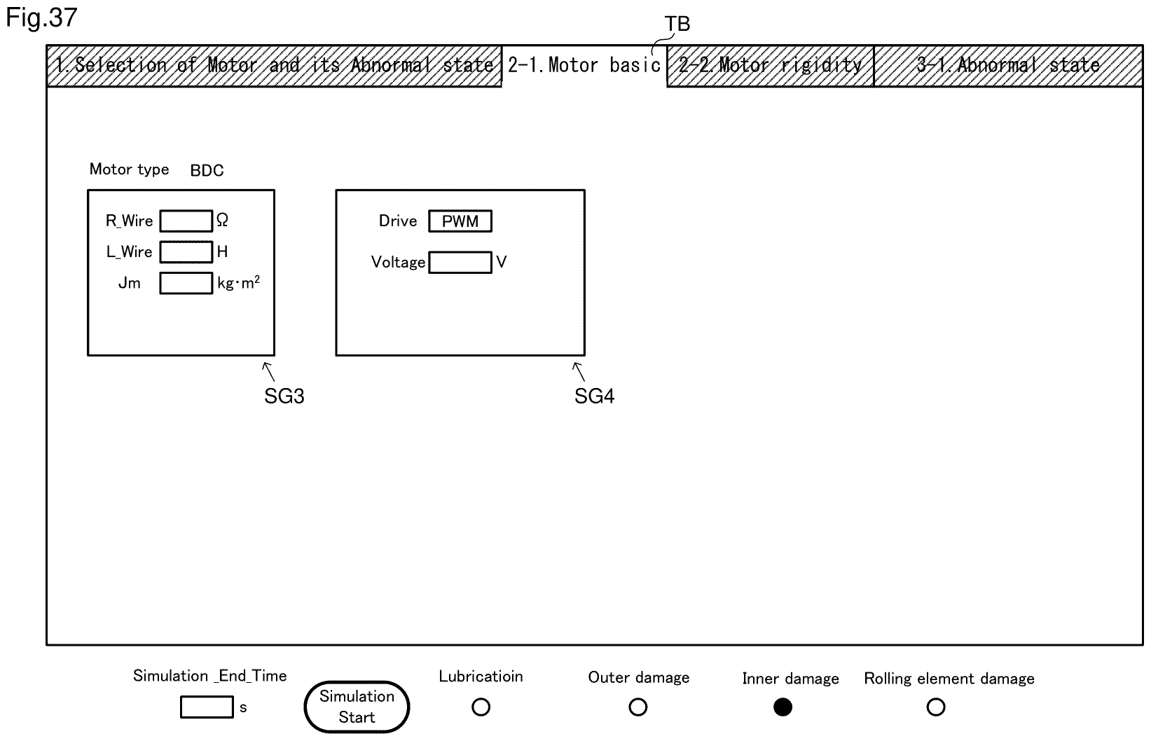

When selecting the neighboring tab TB from the first setting screen, a motor basic setting screen illustrated in FIG. 37 is displayed. In the motor basic setting screen, a basic parameter setting section SG3 and a drive setting section SG4 are displayed. In the basic parameter setting section SG3, with respect to the motor type selected in the first setting screen, basic parameters of the motor can be set. In FIG. 37, wiring resistance (R_Wire), wiring inductance (L_Wire), and inertia (Jm) can be set as an example.

In the drive setting section SG4, with respect to the motor type selected in the first setting screen, a driving method and a drive voltage can be set. For instance, the driving method can be set from constant voltage drive, PWM drive, three-phase drive (square wave drive or sine wave drive drive) and the like. For instance, the drive voltage can be set as a voltage that is applied to the motor terminals in the constant voltage drive, or a high level voltage when applying the voltage to the motor terminals while switching between high level and low level.

Note that in the basic parameter setting section SG3 or the drive setting section SG4, items that can be set may be changed in accordance with the selected motor type.

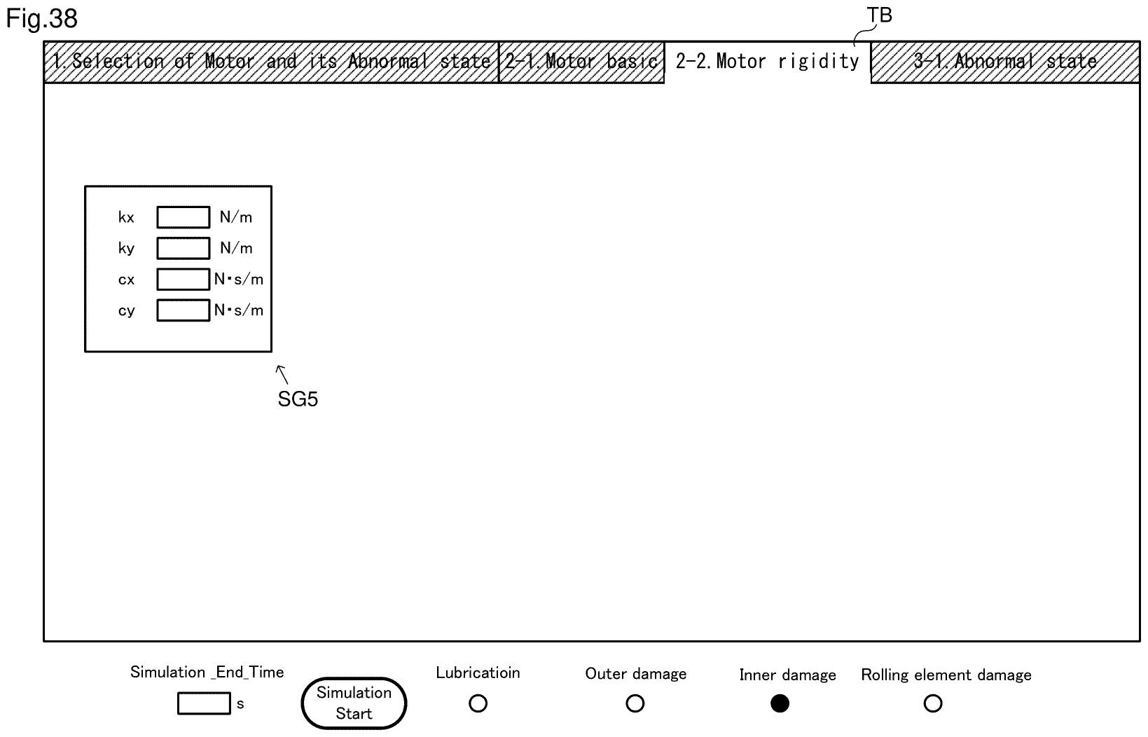

When selecting the neighboring tab TB from the motor basic setting screen, a support system setting screen illustrated in FIG. 38 is displayed. In the support system setting screen, a stiffness and damping characteristic setting section SG5 is displayed. In the stiffness and damping characteristic setting section SG5, the spring constants (stiffness) kx and ky and the damping coefficients cx and cy in the support system vibration model 2114 can be set.

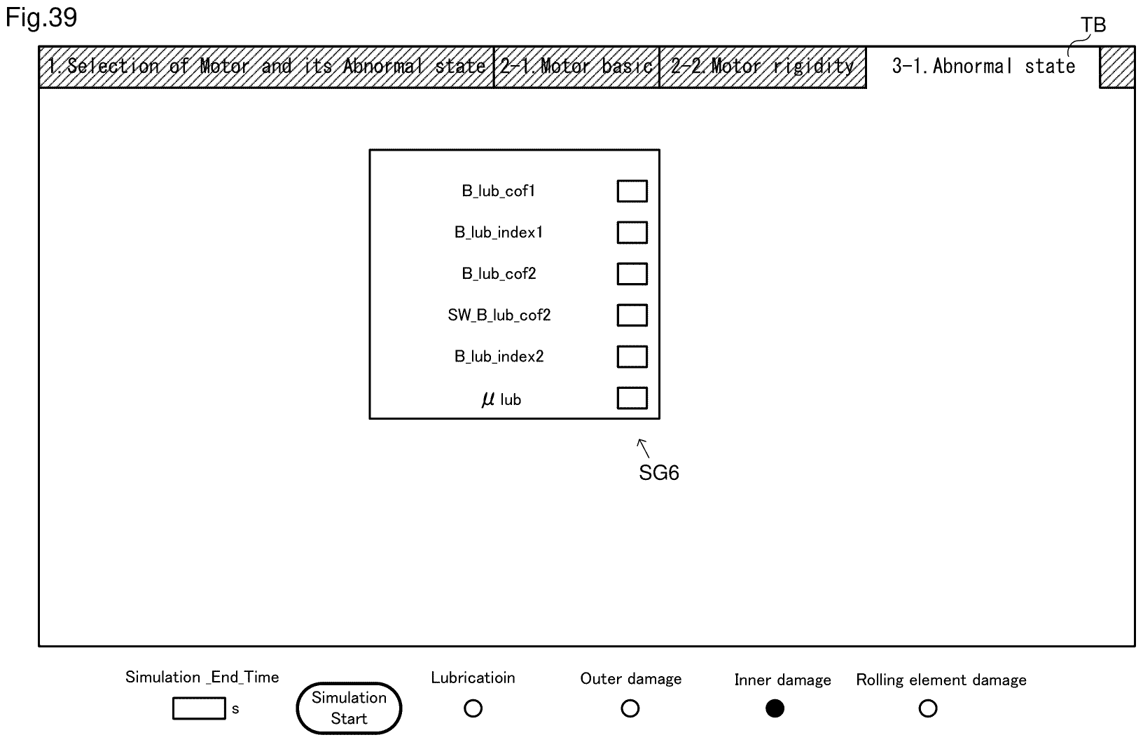

When selecting the neighboring tab TB from the support system setting screen, a first abnormal state setting screen illustrated in FIG. 39 is displayed. In the first abnormal state setting screen, an abnormal parameter setting section SG6 is displayed. In the abnormal parameter setting section SG6, B_{lub_cof1}, B_{lub_index1}, B_{lub_cof2}, SW_B_{lub_cof2}, B_{lub_index2}, and μ_{lub} can be set individually.

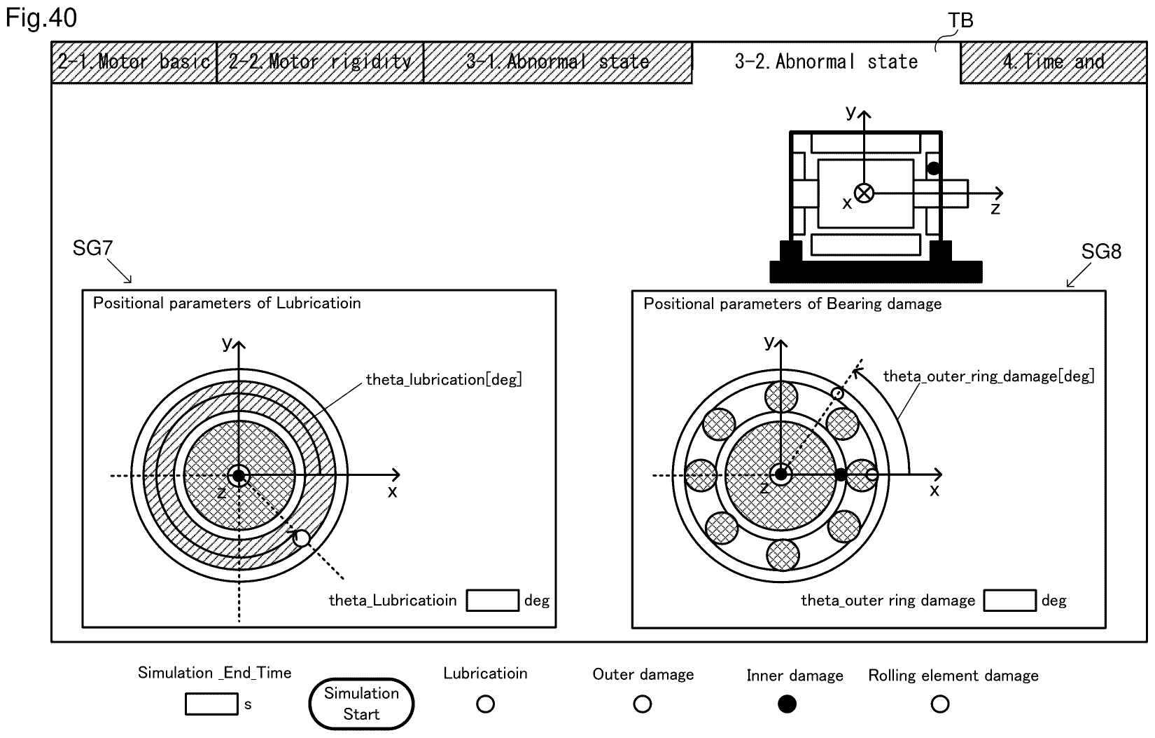

When selecting the neighboring tab TB from the first abnormal state setting screen, a second abnormal state setting screen illustrated in FIG. 40 is displayed. In the second abnormal state setting screen, a lubrication deficiency position setting section SG7 and a bearing damage position setting section SG8 are displayed.

In the lubrication deficiency position setting section SG7, an occurrence point of the lubrication deficiency in the bearing can be set as an angle. In the bearing damage position setting section SG8, an occurrence point of the outer ring damage can be set as an angle. The angle positions set by the lubrication deficiency position setting section SG7 and the bearing damage position setting section SG8 correspond to an angle position θf, which indicates a direction in which the external force F is applied as the normal force due to an abnormality, in the support system vibration model 2114 (FIG. 32).

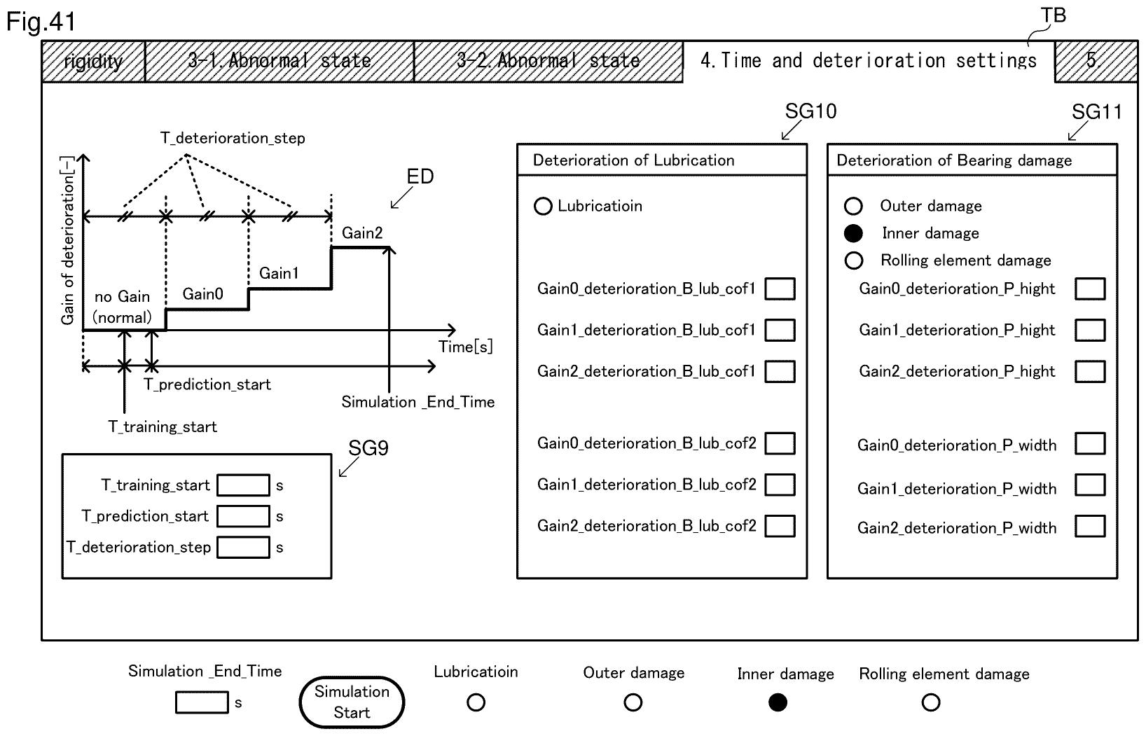

When selecting the neighboring tab TB from the second abnormal state setting screen, a time and deterioration setting screen illustrated in FIG. 41 is displayed. In the time and deterioration setting screen, a time setting section SG9, a lubrication deficiency deterioration setting section SG10, and a bearing damage deterioration setting section SG11 are displayed. In addition, an explanation display ED for explanation is also displayed in the time and deterioration setting screen.

In the time setting section SG9, learning start time, inference start time, and deterioration step time can be set. The learning start time and the inference start time are expressed as elapsed time from the simulation start. The learning start time and the inference start time are displayed in the explanation display ED. Depending on setting of the learning start time, it is possible that data when starting the motor is not used for learning.

As displayed in the explanation display ED, progress of deterioration is expressed by the gain. A state where the gain is zero is the normal state, and the deterioration proceeds from the normal state in a stepwise manner, in order of a first deterioration state Gain0, a second deterioration state Gain1, and a third deterioration state Gain2. The deterioration step time is maximum sustaining time of the normal state or each deterioration state. If the simulation ends before the deterioration step time is completed, the normal state or any deterioration state is sustained for a time period shorter than the deterioration step time.

In the lubrication deficiency deterioration setting section SG10, a gain value of each of the first to third deterioration states can be set for each of the constant coefficient B_{lub_cof1} and the B_{lub_cof2}, in the above equation (3) for calculating the friction torque due to bearing lubrication deficiency. For instance, the gain value 0 indicates a coefficient value in the normal state, the gain value 1 indicates a coefficient value in a given abnormal state (set in the abnormal parameter setting section SG6), the gain value 0.5 indicates 0.5 times the coefficient value in the given abnormal state, the gain value 2 indicates 2 times the coefficient value in the given abnormal state, and the gain value 4 indicates 4 times the coefficient value in the given abnormal state. As the gain value is larger, the coefficient is larger, which indicates that the deterioration of the lubrication deficiency has proceeded.

In the bearing damage deterioration setting section SG11, the gain value of each of the first to third deterioration states can be set for each of the height P_{hight} and the width P_{width} of the shock pulse, due to the bearing damage (damage of the outer ring, the inner ring, or the rolling element). A specific example of the gain values is the same as that of the coefficient described above. As the gain value is larger, the height and the width of the shock pulse are larger, which indicates that the deterioration has proceeded.

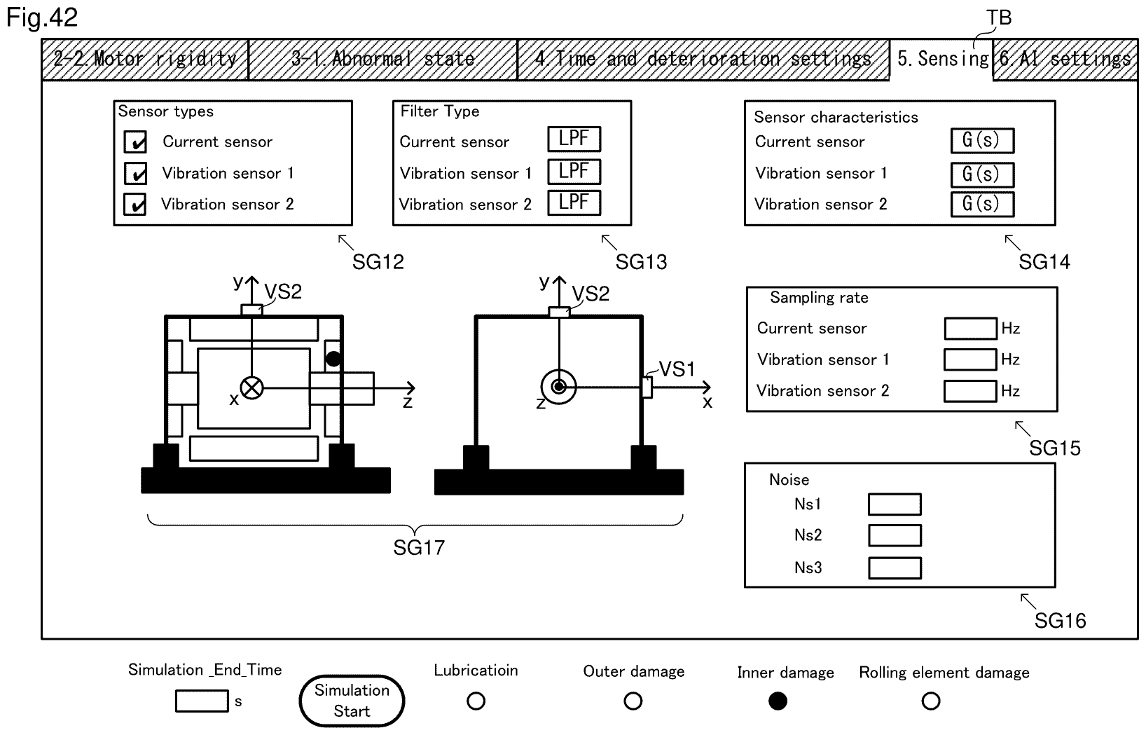

When selecting the neighboring tab TB from the time and deterioration setting screen, a sensor setting screen illustrated in FIG. 42 is displayed. In the sensor setting screen, a sensor type setting section SG12, a filter setting section SG13, a sensor characteristic setting section SG14, a sampling speed setting section SG15, and a noise setting section SG16 are displayed.

In the sensor type setting section SG12, a sensor type in the sensor model 22 can be selected. In FIG. 42, at least one of the current sensor, a first vibration sensor, and a second vibration sensor can be selected, as an example. The transfer function model 221 and the AD conversion model 222 illustrated in FIG. 33 are disposed for each sensor type. The current sensor receives the motor terminal current as the physical signal waveform from the motor model 211, and outputs a current sense signal. The first vibration sensor and the second vibration sensor each receive displacement and acceleration as the physical signal waveform from the motor model 211, and each output a displacement sense signal and an acceleration sense signal.

In the filter setting section SG13, setting about the filter (included in the transfer function model 221) in the sensor model 22 can be performed. The filter is added in consideration of noise reduction, or a frequency range of the sensor and Nyquist frequency. The filter can be set for each sensor type. For instance, a type of the filter (low pass filter (LPF), band pass filter (BPF), or the like), and a parameter about the filter (such as a cut-off frequency) can be set.

In the sensor characteristic setting section SG14, characteristic of the sensor itself can be set for each sensor type. For instance, frequency characteristic of the sensor itself can be expressed by a transfer function (LPF, BPF, or the like). In FIG. 42, G(s) indicates the transfer function, and s is a Laplace operator.

In the sampling speed setting section SG15, the sampling speed in the AD conversion model 222 can be set. The sampling speed can be set for each sensor type.

In the noise setting section SG16, a type and a parameter of each of the noises Ns1, Ns2, and Ns3 can be set.

In addition, in the sensor setting screen, a sensor position setting section SG17 is also displayed. In the sensor position setting section SG17, a position of the sensor can be set. By selecting the sensor with the operation input unit 6, and by moving the same on the screen, the position of the sensor can be set. In FIG. 42, a first vibration sensor VS1 and a second vibration sensor VS2 are displayed as an example, and the positions of the first vibration sensor VS1 and the second vibration sensor VS2 can each be set. In FIG. 42, the first vibration sensor VS1 is arranged on the X-axis, and the second vibration sensor VS2 is arranged on the Y-axis.

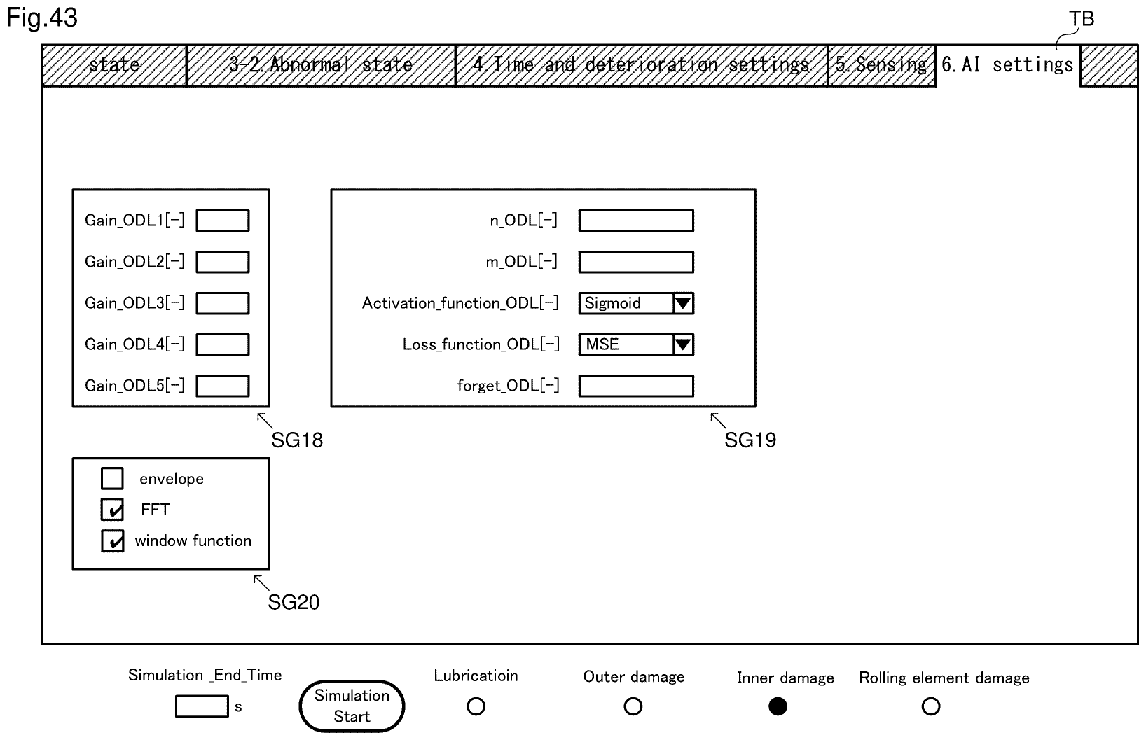

When selecting the neighboring tab TB from the sensor setting screen, an AI setting screen illustrated in FIG. 43 is displayed. In the AI setting screen, a normalization coefficient setting section SG18 and a machine learning setting section SG19 are displayed.

The preprocessing section 231 and the machine learning section 232 of the machine learning model 23 are disposed for each sense signal output from the sensor model 22. The preprocessing section 231 and the machine learning section 232 are disposed for each of the current sense signal output from the current sensor, the displacement sense signal and the acceleration sense signal output from the first vibration sensor, and the displacement sense signal and the acceleration sense signal output from the second vibration sensor (five sense signals), as an example.

In the normalization coefficient setting section SG18, the normalization coefficient for the preprocessing section 231 of each sense signal to perform normalization can be set. In FIG. 43, the normalization coefficient for each of the five sense signals described above can be set, as an example.

In the machine learning setting section SG19, various items related to the machine learning section 232 can be set. In FIG. 43, the number of input data n, the number of hidden layer nodes m, the activation function, the loss function, and the forgetting rate can be set for the three-layer neural network 30 (FIG. 35), as an example. As the activation function, for example, Sigmoid, ReLU, or the like can be set. In addition, as the loss function, for example, MAE or MSE can be set.

In addition, in the AI setting screen, a preprocess setting section SG20 is also displayed. In the preprocess setting section SG20, presence or absence of each of the envelope processing, the FFT processing (frequency analysis processing), and the window function processing can be set.

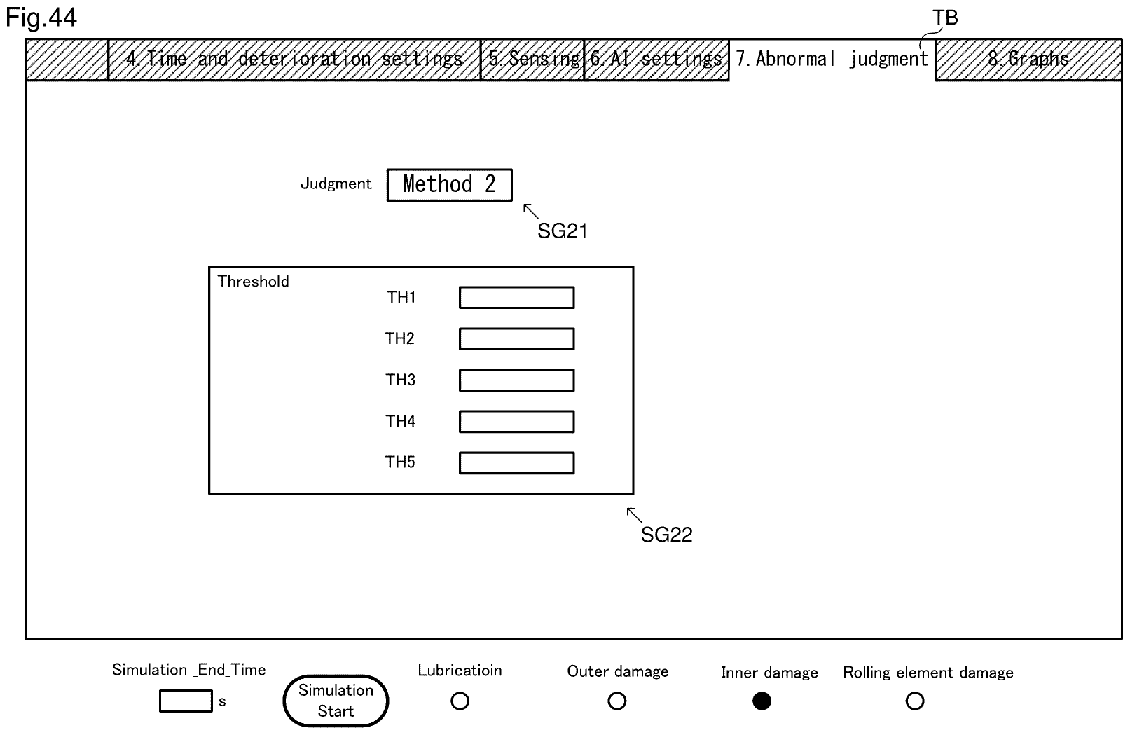

When selecting the neighboring tab TB from the AI setting screen, an abnormality determination setting screen illustrated in FIG. 44 is displayed. In the abnormality determination setting screen, an abnormality determination method setting section SG21 and an abnormality determination threshold value setting section SG22 are displayed.

In the abnormality determination method setting section SG21, an abnormality determination method based on the abnormality degree in the abnormality determination model 24 can be selected. In FIG. 44, a first determination method (Method 1) or a second determination method (Method 2) can be selected, as an example. The first determination method is a method of comparing the abnormality degree with one threshold value, so as to determine abnormality or normality. The second determination method is a method of comparing the abnormality degree with a plurality of threshold values, so as to determine different abnormality levels in a stepwise manner.

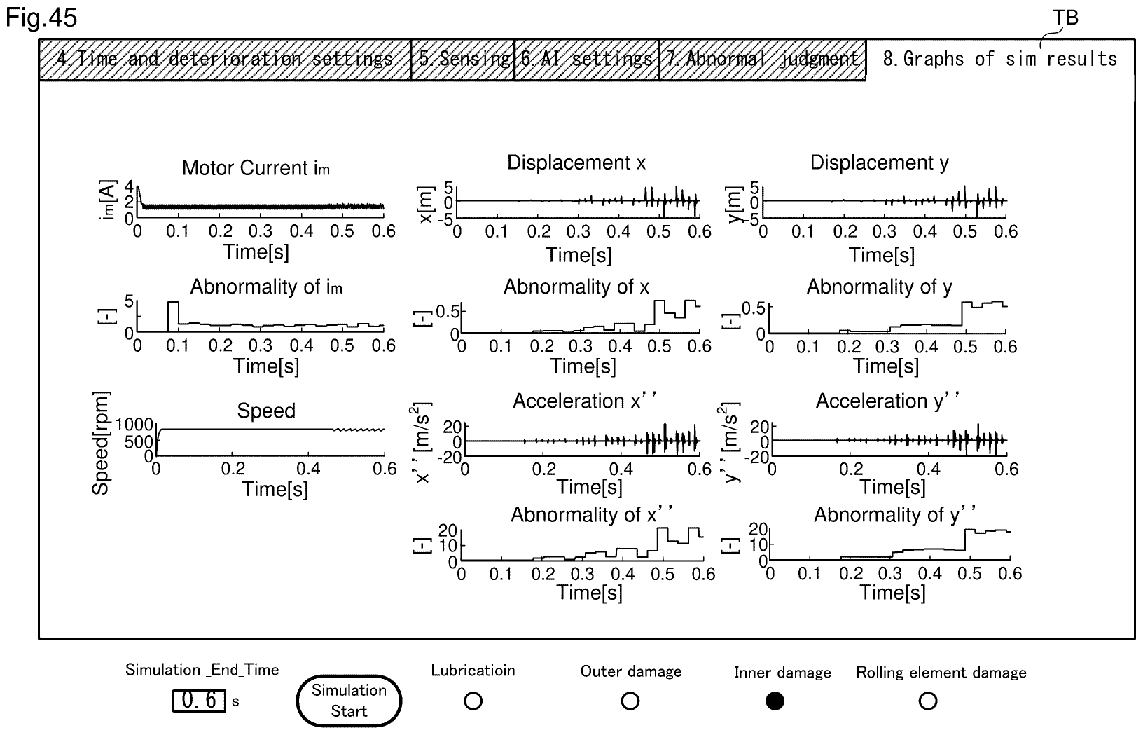

In the abnormality determination threshold value setting section SG22, threshold values to be used in the selected abnormality determination method can be set. After all setting items are set on the setting screens described above, the simulation start button SB is pressed by the operation input unit 6, and then the model arithmetic unit 3 executes the simulation in accordance with the contents set by the model setting unit 4. After the simulation is completed, when the tab TB of the simulation result screen illustrated in FIG. 45 is pressed by the operation input unit 6, the display control unit 5 displays the simulation result on the display unit 7.

In the simulation result screen, the time-series data of the sense signals of the sensors selected as described above, and the time-series data of the abnormality degrees corresponding to the sense signals can be displayed. In FIG. 45, the time-series data of the motor terminal current, the displacement in the X direction, the displacement in the Y direction, the acceleration in the X direction, and the acceleration in the Y direction, as well as the time-series data of the abnormality degrees of the motor terminal current, the displacement in the X direction, the displacement in the Y direction, the acceleration in the X direction, and the acceleration in the Y direction are displayed, as an example. Note that as illustrated in FIG. 42, the first vibration sensor VS1 is disposed on the X-axis while the second vibration sensor VS2 is disposed on the Y-axis, and hence the displacement in the X direction and the acceleration in the X direction are detected by the first vibration sensor VS1, while the displacement in the Y direction and the acceleration in the Y direction are detected by the second vibration sensor.

Note that it may be possible to display time-series data of the abnormality determination result in the abnormality determination model 24, or the FFT processing result (power spectrum) in the preprocessing section 231 (FIG. 34).

In this way, using the GUI, simulation conditions can be intuitively set, and by performing simulation and by checking the simulation result, it is possible to check the effect of detection of signs of abnormality in the motor using machine learning.

### OTHERS

Note that besides the above embodiment, various technical features disclosed in this specification can be variously modified within the scope of the technical creation without deviating from the spirit thereof. In other words, the above embodiment is merely an example in all aspects and should not be interpreted as a limitation. The technical scope of the present disclosure is not limited to the above embodiment, but should be understood to include all modifications in meaning and scope equivalent to the claims.

### ADDITIONAL REMARKS

As described above, a simulation apparatus (1) according to one aspect of the present disclosure comprises:
a model storage unit (2) storing
   a physical model (211) of a physical system configured to generate a physical signal waveform,
   a sensor model (22) configured to receive data based on the physical signal waveform data so as to output a sense signal,
   a machine learning model (23) configured to receive the sense signal so as to perform learning and inference, and
   an abnormality determination model (24) configured to receive an abnormality degree as error data output from the machine learning model so as to perform abnormality determination;
a model arithmetic unit (3) configured to perform arithmetic processing using the physical model, the sensor model, the machine learning model, and the abnormality determination model;
an operation input unit (6); and
a model setting unit (4) configured to perform setting related to each of the physical model, the sensor model, the machine learning model, and the abnormality determination model, on the basis of an input from the operation input unit (first structure).

In addition, in the first structure, it may be possible to adopt a structure (second structure) wherein the physical model is a motor model (211) obtained by modeling a motor.

In addition, in the second structure, it may be possible to adopt a structure (third structure, FIG. 36) wherein the model setting unit can select and set at least one of a type of the motor and an abnormal state of the motor.

In addition, in the second or third structure, it may be possible to adopt a structure (fourth structure, FIG. 37) wherein the model setting unit can set at least one of a parameter of a mechanical element constituting the motor and an item related to driving of the motor.

In addition, in any one of the second through fourth structures, it may be possible to adopt a structure (fifth structure) wherein
the motor model includes an abnormal state model (211A) obtained by modeling an abnormal state of the motor, and
the model setting unit can set a parameter change in the abnormal state model corresponding to progress of deterioration of the motor.

In addition, in the fifth structure, it may be possible to adopt a structure (sixth structure) wherein the abnormal state model includes a bearing lubrication deficiency model (2112) obtained by modeling bearing lubrication deficiency of the motor.

In addition, in the sixth structure, it may be possible to adopt a structure (seventh structure) wherein
the bearing lubrication deficiency model includes a first equation for calculating a friction torque due to lubrication deficiency, and
the model setting unit can set at least one of a constant coefficient of the term depending on a mechanical angular velocity in the first equation, a function of a mechanical angle in the term, and an index of the mechanical angular velocity in the term.

In addition, in the seventh structure, it may be possible to adopt a structure (eighth structure) wherein
the motor model includes a support system vibration model (2114) in the case where all mechanical elements constituting the motor are defined as a support system,
the bearing lubrication deficiency model includes a second equation for calculating a normal force due to lubrication deficiency, on the basis of the friction torque, and
the normal force calculated by the second equation is input to the support system vibration model.

In addition, in the eighth structure, it may be possible to adopt a structure (ninth structure, FIG. 40) wherein the model setting unit can set an occurrence point of lubrication deficiency.

In addition, in any one of the fifth through ninth structures, it may be possible to adopt a structure (tenth structure) wherein the abnormal state model includes a bearing damage model (2113) obtained by modeling a damage of a mechanical element constituting a bearing of the motor.

In addition, in the tenth structure, it may be possible to adopt a structure (eleventh structure, FIG. 41) wherein
the motor model includes the support system vibration model (2114) in the case where all mechanical elements constituting the motor are defined as a support system,
the bearing damage model is modeled supposing that the normal force due to a damage occurs, having a height of the shock pulse, in the case where an angle based on a revolution angle or a rotation angle of a rolling element included in the bearing is within an angle range based on a width of the shock pulse,
the normal force is input to the support system vibration model, and
the model setting unit can set at least one of the height of the shock pulse and the width of the shock pulse.

In addition, in the eleventh structure, it may be possible to adopt a structure (twelfth structure, FIG. 40) wherein the model setting unit can set a damage occurrence point of an outer ring included in the bearing.

In addition, in any one of the eighth, ninth, eleventh, and twelfth structures, it may be possible to adopt a structure (thirteenth structure, FIG. 38) wherein
the support system vibration model is modeled by an equation of motion for a structure in which a parallel connection configuration of a spring (Kx, Ky) and a damper (Cx, Cy) is connected to a particle including the support system, and
the model setting unit can set at least one of a spring constant of the spring and a damping coefficient of the damper.

In addition, in any one of the first through thirteenth structures, it may be possible to adopt a structure (fourteenth structure, FIG. 42) wherein the model setting unit can select and set a type of the sensor modeled by the sensor model.

In addition, in any one of the first through fourteenth structures, it may be possible to adopt a structure (fifteenth structure, FIG. 42) wherein
the sensor model includes a transfer function model (221) and an AD conversion model (222), and
the model setting unit can perform setting related to at least one of the transfer function model and the AD conversion model.

In addition, in any one of the first through fifteenth structures, it may be possible to adopt a structure (sixteenth structure, FIG. 42) wherein the model setting unit can set an arrangement position of the sensor modeled by the sensor model.

In addition, in any one of the first through sixteenth structures, it may be possible to adopt a structure (seventeenth structure, FIG. 43) wherein
the machine learning model includes a machine learning section (232) modeled by an AI model (30), and
the model setting unit can set an item related to the machine learning section.

In addition, in the seventeenth structure, it may be possible to adopt a structure (eighteenth structure, FIG. 43) wherein
the machine learning model includes a preprocessing section (231) in a former part of the machine learning section, and
the model setting unit can set at least one of presence or absence of envelope processing, presence or absence of frequency analysis processing, and presence or absence of window function processing, in the preprocessing section.

In addition, in the seventeenth or eighteenth structure, it may be possible to adopt a structure (nineteenth structure, FIG. 43) wherein
the machine learning model includes a preprocessing section in a former part of the machine learning section, and
the model setting unit can set a normalization coefficient for a normalization process to keep data within a predetermined range in the preprocessing section.

In addition, in any one of the first through nineteenth structures, it may be possible to adopt a structure (twentieth structure, FIG. 41) wherein the model setting unit can set learning start timing and inference start timing of the machine learning model.

In addition, in any one of the first through twentieth structures, it may be possible to adopt a structure (twenty-first structure, FIG. 44), wherein the model setting unit can set a method of comparing between a threshold value and a value based on the abnormality degree, in the abnormality determination unit.

In addition, in any one of the first through twenty-first structures, it may be possible to adopt a structure (twenty-second structure, FIG. 45) including a display control unit (5) configured to allow a display unit to display at least one of time-series data of the sense signal, time-series data of the abnormality degree, time-series data of abnormality determination result by the abnormality determination unit, and a frequency analysis result of the time-series data of the sense signal, as a result of simulation performed by the model arithmetic unit.

In addition, in any one of the first through twenty-second structures, it may be possible to adopt a structure (twenty-third structure) including a data storage unit (8) configured to store state monitor data (DT) obtained from outside of the simulation apparatus, wherein
the model arithmetic unit allows the machine learning model to receive the state monitor data so as to perform simulation.

In addition, a program (P) according to one aspect of the present disclosure is a program for allowing a computer (100) to work as the simulation apparatus having any one of the first through twenty-third structures.

What is claimed is:

1. A simulation apparatus comprising:
a model storage unit storing
a physical model of a physical system configured to generate a physical signal waveform,
a sensor model configured to receive data based on the physical signal waveform data so as to output a sense signal,
a machine learning model configured to receive the sense signal so as to perform learning and inference, and
an abnormality determination model configured to receive an abnormality degree as error data output from the machine learning model so as to perform abnormality determination;
a model arithmetic unit configured to perform arithmetic processing using the physical model, the sensor model, the machine learning model, and the abnormality determination model;
an operation input unit; and
a model setting unit configured to perform setting related to each of the physical model, the sensor model, the machine learning model, and the abnormality determination model, on the basis of an input from the operation input unit.

2. The simulation apparatus according to claim 1, wherein the physical model is a motor model obtained by modeling a motor.

3. The simulation apparatus according to claim 2, wherein the model setting unit can select and set at least one of a type of the motor and an abnormal state of the motor.

4. The simulation apparatus according to claim 2, wherein the model setting unit can set at least one of a parameter of a mechanical element constituting the motor and an item related to driving of the motor.

5. The simulation apparatus according to claim 2, wherein
the motor model includes an abnormal state model obtained by modeling an abnormal state of the motor, and
the model setting unit can set a parameter change in the abnormal state model corresponding to progress of deterioration of the motor.

6. The simulation apparatus according to claim 5, wherein the abnormal state model includes a bearing lubrication deficiency model obtained by modeling bearing lubrication deficiency of the motor.

7. The simulation apparatus according to claim 6, wherein
the bearing lubrication deficiency model includes a first equation for calculating a friction torque due to lubrication deficiency, and
the model setting unit can set at least one of a constant coefficient of the term depending on a mechanical angular velocity in the first equation, a function of a mechanical angle in the term, and an index of the mechanical angular velocity in the term.

8. The simulation apparatus according to claim 7, wherein
the motor model includes a support system vibration model in the case where all mechanical elements constituting the motor are defined as a support system,
the bearing lubrication deficiency model includes a second equation for calculating a normal force due to lubrication deficiency, on the basis of the friction torque, and
the normal force calculated by the second equation is input to the support system vibration model.

9. The simulation apparatus according to claim 5, wherein the abnormal state model includes a bearing damage model obtained by modeling a damage of a mechanical element constituting a bearing of the motor.

10. The simulation apparatus according to claim 9, wherein
the motor model includes a support system vibration model in the case where all mechanical elements constituting the motor are defined as a support system,
the bearing damage model is modeled supposing that the normal force due to a damage occurs, having a height of the shock pulse, in the case where an angle based on a revolution angle or a rotation angle of a rolling element included in the bearing is within an angle range based on a width of the shock pulse,
the normal force is input to the support system vibration model, and
the model setting unit can set at least one of the height of the shock pulse and the width of the shock pulse.

11. The simulation apparatus according to claim 8, wherein
the support system vibration model is modeled by an equation of motion for a structure in which a parallel connection configuration of a spring and a damper is connected to a particle including the support system, and
the model setting unit can set at least one of a spring constant of the spring and a damping coefficient of the damper.

12. The simulation apparatus according to claim 1, wherein the model setting unit can select and set a type of the sensor modeled by the sensor model.

13. The simulation apparatus according to claim 1, wherein
the machine learning model includes a machine learning section modeled by an AI model, and
the model setting unit can set an item related to the machine learning section.

14. The simulation apparatus according to claim 13, wherein
the machine learning model includes a preprocessing section in a former part of the machine learning section, and
the model setting unit can set at least one of presence or absence of envelope processing, presence or absence of frequency analysis processing, and presence or absence of window function processing, in the preprocessing section.

15. The simulation apparatus according to claim 13, wherein
the machine learning model includes a preprocessing section in a former part of the machine learning section, and
the model setting unit can set a normalization coefficient for a normalization process to keep data within a predetermined range in the preprocessing section.

16. The simulation apparatus according to claim 1, further comprising a data storage unit configured to store state monitor data obtained from outside of the simulation apparatus, wherein
the model arithmetic unit allows the machine learning model to receive the state monitor data so as to perform simulation.

17. A program for allowing a computer to work as the simulation apparatus according to claim 1.
